(19) United States
(12) Patent Application Publication
(10) Pub. No.: US 2026/0317350 A1
(43) Pub. Date: Oct. 15, 2026

(54) Composition Containing Organosilane Compounds, Methods of Manufacturing Thin Films and Thin Film-Coated Substrates, Transfer Method, Thin Film-Coated Substrate, and Article

(71) Applicants: Mitsubishi Chemical Corporation, Tokyo (JP); Gelest, Inc., Morrisville, PA (US)

(72) Inventors: Minori Suzuki, Tokyo (JP); Yuta Hioki, Tokyo (JP); Yoshie Takami, Tokyo (JP); Akiteru FUJII, Tokyo (JP)

(21) Appl. No.: 19/578,273

(22) Filed: Mar. 25, 2026

Related U.S. Application Data
(60) Provisional application No. 63/779,584, filed on Mar. 28, 2025.
(60) Provisional application No. 63/872,630, filed on Aug. 29, 2025.

(51) Int. Cl. C07F 7/18; B05D 1/00; C23C 16/455

(52) U.S. Cl. CPC C07F 7/1804; B05D 1/005; C23C 16/45553; B05D 2202/00

(57) ABSTRACT

A composition containing specific silane compounds can achieve a deposition rate sufficient to ensure productivity in industrial production and form a uniform thin film. The composition includes a silane compound having formula (1). A content of the silane compound as calculated from the area percentages in gas chromatography is 95.0% or higher and the composition contains additional specific silane compounds at specific concentrations.

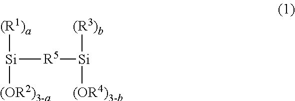

In formula (1), R¹ to R⁴ represent the same or different hydrocarbon groups with 1 to 10 carbon atoms, a and b represent the same or different integers of 0 to 3, a+b is an integer of 5 or less, and R⁵ represents a hydrocarbon group with 1 to 6 carbon atoms.

### CROSS-REFERENCE TO RELATED APPLICATION

This application claims priority to U.S. Provisional Application No. 63/779,584, filed Mar. 28, 2025 and U.S. Provisional Application No. 63/872,630, filed on Aug. 29, 2025, the disclosures of which are herein incorporated by reference in their entireties.

### TECHNICAL FIELD

Aspects of the disclosure relate to a composition containing organosilane compounds. This disclosure also relates to a composition containing specific proportions of organosilane compounds having specific structures for use in applications such as semiconductor materials. This disclosure also relates to a method of manufacturing thin films using the composition containing the organosilane compounds. Further aspects of the disclosure relate to a method of manufacturing thin film-coated substrates and to thin film-coated substrates formed from the composition containing the organosilane compounds. This disclosure also relates to a method of transferring the composition containing the organosilane compounds and to an article in which the composition containing the organosilane compounds is contained in a sealed container.

### BACKGROUND OF THE INVENTION

### Background Art

In recent years, as the degree of integration and miniaturization of semiconductor integrated circuits has progressed, problems such as a decrease in signal transmission speed in wiring and an increase in power consumption have become more serious, and high performance of insulating films used in each step of semiconductor manufacturing is required. In particular, in the case of forming thin structures or complex structures in semiconductor materials, or when a very thin interlayer insulating film is required, it is important to form a high-performance film that satisfies the necessary properties (such as dielectric constant and mechanical strength) for each purpose by film formation in deposition conditions such as CVD (Chemical Vapor Deposition) or ALD (Atomic Layer Deposition).

Therefore, in addition to the conventionally used insulating film material SiO₂ (dielectric constant 4.0) that uses a material such as tetraethoxysilane (TEOS) as its precursor, high-performance insulating films using precursors consisting of organosilane compounds with different structures and compositions have been proposed. For example, U.S. Patent Application Publication No. 2006/0165891 discloses a CVD method for forming a film containing Si, C, O, and H atoms (SiCOH) with a lower dielectric constant (k). This method describes the use of precursors containing specific chemical structures, such as Si—CH₂—Si or Si—CH₃, to introduce these structures into the insulating film, thereby making it possible to form a low-dielectric constant film.

On the other hand, a method for synthesizing these precursors with specific structures at the high purity levels required for semiconductor applications has been reported. For example, U.S. Patent Application Publication No. 2011/0082309 and U.S. Patent Application Publication No. 2009/0299086 describe a manufacturing method for synthesizing compounds (X₃Si—R—SiX₃) with a specific Si—CH₂—Si structure at high purity in high efficiency.

### SUMMARY OF THE INVENTION

### Problem to be Solved by the Invention

However, while a demand for further miniaturization, cost reduction, and optimization of functionality in insulating film precursors has emerged in recent years, no material that fully satisfies these requirements has yet been found. More specifically, even when attempting to introduce a precursor with a specific structure and with sufficient purity into a film, the deposition rate becomes insufficient due to an inadequate reaction rate of the corresponding precursor, resulting in poor productivity when used industrially. Furthermore, when using additives to accelerate the reaction rate of the precursors, which is the reaction rate of CVD or ALD precursors, it is necessary to consider other precursors that can accelerate the reaction without degrading the functionality of the film formed by the basic precursor. However, the structures and compositions of such precursors have not been sufficiently studied.

In light of this background, there has been a need for a material with a low dielectric constant, capable of serving as a precursor for CVD or ALD, and having a deposition rate that can withstand industrial production, or in other words, a precursor that boasts an appropriate reaction rate.

### Means for Solving the Problem

In their efforts to solve the aforementioned problems, the inventors have discovered that, by combining specific silane compounds with particular chemical structures in a specific balance in relation to a given silane compound, these problems can be solved.

In other words, the present invention has the following aspects:

(1)

A composition comprising a silane compound 1 having formula (1) and a silane compound 2 having formula (2), wherein, as calculated from area percentages in gas chromatography, a content of the silane compound 1 is 95.0% or higher, a content of the silane compound 2 is 0.05 to 5.0%, and wherein the composition contains less than 0.01% of a silane compound 3 having formula (3):

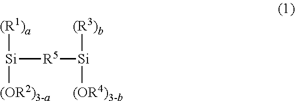

wherein R¹ to R⁴ represent the same or different hydrocarbon groups having 1 to 10 carbon atoms, a and b represent the same or different integers of 0 to 3, a+b is an integer of 5 or less, and R⁵ represents a hydrocarbon group with 1 to 6 carbon atoms;

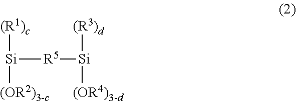

wherein c and d represent the same or different integers of 0 to 3, the sum of c and d is greater than the sum of a and b in formula (1);

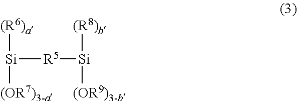

wherein R⁶ to R⁹ represent the same or different hydrocarbon groups having 1 to 10 carbon atoms, and a′ and b′ represent the same or different integers from 0 to 3.
(2)

A composition comprising a silane compound 1 having formula (1) and a silane compound 3 having formula (3); wherein, as calculated from area percentages in gas chromatography, a content of the silane compound 1 is 90.0% or higher, a content of the silane compound 3 is 0.80 to 10.0%, and wherein the composition contains less than 0.01% of a silane compound 2 having formula (2):

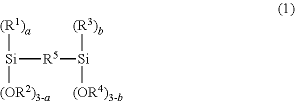

wherein R¹ to R⁴ represent the same or different hydrocarbon groups having 1 to 10 carbon atoms, a and b represent the same or different integers of 0 to 3, a+b is an integer of 5 or less, and R⁵ represents a hydrocarbon group with 1 to 6 carbon atoms;

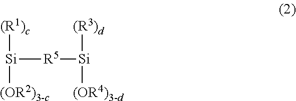

wherein c and d represent the same or different integers of 0 to 3, the sum of c and d is greater than the sum of a and b in formula (1);

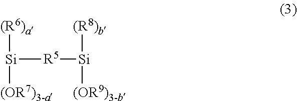

wherein R⁶ to R⁹ represent the same or different hydrocarbon groups having 1 to 10 carbon atoms, and a′ and b′ represent the same or different integers from 0 to 3.
(3)

A composition comprising a silane compound 1 having formula (1), a silane compound 2 having formula (2), and a silane compound 3 having formula (3); wherein, as calculated from area percentages in gas chromatography, a content of the silane compound 1 is 95.0% or higher, a content of the silane compound 2 is 0.05 to 2.0%, and a content of the silane compound 3 is 0.05 to 2.0%:

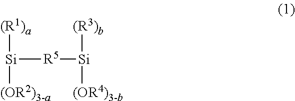

wherein R¹ to R⁴ represent the same or different hydrocarbon groups having 1 to 10 carbon atoms, a and b represent the same or different integers of 0 to 3, a+b is an integer of 5 or less, and R⁵ represents a hydrocarbon group with 1 to 6 carbon atoms;

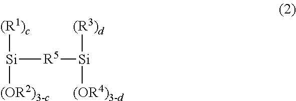

wherein c and d represent the same or different integers of 0 to 3, the sum of c and d is greater than the sum of a and b in formula (1);

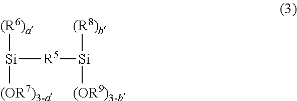

wherein R⁶ to R⁹ represent the same or different hydrocarbon groups having 1 to 10 carbon atoms, and a′ and b′ represent the same or different integers from 0 to 3.
(4)

The composition of (1), wherein the content of the silane compound 2 is 0.10 to 2.0%.

(5)

The composition of (2), wherein the content of the silane compound 3 is 0.90 to 5.0%.

(6)

The composition of (3), wherein the content of the silane compound 1 is 99.0% or higher, the content of the silane compound 2 is 0.05 to 0.20%, and the content of the silane compound 3 is 0.05 to 0.20%.

(7)

The composition of any one of (1) to (6), wherein in formula (1), a and b represent the same or different integers of 0 to 2, and in formula (2), c and d represent the same or different integers of 0 to 2.

(8)

The composition of any one of (1) to (7), further comprising an additional silane compound 5 having formula (5), wherein a content of the additional silane compound 5, as calculated from an area percentage in gas chromatography, is 0.10 to 2.0%:

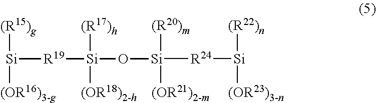

wherein R¹⁵ to R¹⁸ and R²⁰ to R²³ represent the same or different hydrocarbon groups having 1 to 10 carbon atoms, g and n represent the same or different integers of 0 to 3, h and m represent the same or different integers of 0 to 2, and R¹⁹ and R²⁴ represent the same or different hydrocarbon groups having 1 to 6 carbon atoms.
(9)

The composition of any of (1) to (8), wherein a halogen content is 10 mass ppm or less for each halogen atom.

(10)

A composition comprising a silane compound 1 having formula (1) and a silane compound 5 having formula (5), wherein, as calculated from area percentages in gas chromatography, a content of the silane compound 1 is 95.0% or higher and a content of the silane compound 5 is 0.05 to 2.0%, and wherein the composition contains less than 0.01% of a silane compound 2 having formula (2) and less than 0.01% of a silane compound 3 having formula (3), and wherein a chlorine atom content is 9 mass ppm or less:

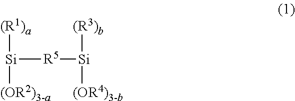

wherein R¹ to R⁴ represent the same or different hydrocarbon groups having 1 to 10 carbon atoms, a and b represent the same or different integers of 0 to 3, a+b is an integer of 5 or less, and R⁵ represents a hydrocarbon group having 1 to 6 carbon atoms;

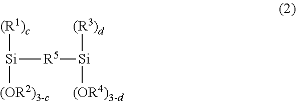

wherein c and d represent the same or different integers of 0 to 3, the sum of c and d is greater than the sum of a and b in formula (1);

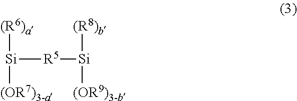

wherein R⁶ to R⁹ represent the same or different hydrocarbon groups having 1 to 10 carbon atoms, and a′ and b′ represent the same or different integers from 0 to 3;

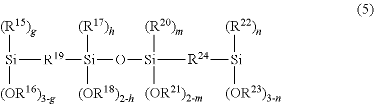

wherein R¹⁵ to R¹⁸ and R²⁰ to R²³ represent the same or different hydrocarbon groups having 1 to 10 carbon atoms, g and n represent the same or different integers of 0 to 3, h and m represent the same or different integers of 0 to 2, and R¹⁹ and R²⁴ represent the same or different hydrocarbon groups having 1 to 6 carbon atoms.
(11)

The composition of any of (1) to (10), wherein a metal content is 100 mass ppb or less for each metal element.

(12)

The composition of any of (1) to (11), wherein the composition is substantially free of solvent.

(13)

The composition of any one of (1) to (12), wherein the composition is used for chemical vapor deposition (CVD) or atomic layer deposition (ALD).

(14)

A method for manufacturing a thin film, comprising forming a thin film by chemical vapor deposition (CVD) or atomic layer deposition (ALD) using the composition of any one of (1) to (13).

(15)

A method for manufacturing a thin film on a substrate, comprising vaporizing the composition of any one of (1) to (13), introducing the vaporized composition into a reaction chamber, and forming a thin film on a substrate in the reaction chamber using the vaporized composition.

(16)

The method for manufacturing of (15), wherein the composition is vaporized by an injection method.

(17)

A transfer method comprising vaporizing the composition of any one of (1) to (13) and transporting the vaporized composition through a pipeline.

(18)

A thin film on a substrate obtained by the manufacturing method of (15).

(19)

A method for manufacturing a thin film, comprising spin coating a thin film using the composition of any one of (1) to (13).

(20)

An article containing a composition of any one of (1) to (13) in a sealed container having one or more pipelines.

(21)

The article of (20), wherein the sealed container is a metal pressure vessel.

(22)

The method for manufacturing as described in (15) or (16), wherein the composition is vaporized without introducing a carrier gas into the composition.

(23)

The thin film on a substrate according to (18), wherein an in-plane uniformity is within +5% and a hardness is 1 GPa or more.

(24)

The method for manufacturing a thin film according to (14), wherein an in-plane uniformity is within ±5% and a hardness is 1 GPa or more.

### Effect of the Invention

In the compositions according to the present disclosure, which may be used as film-forming materials, by including a specific silane compound in a specific proportion in addition to silane compound 1, which is the main component of the composition, the reaction between silane compounds can be accelerated, thereby making it possible to achieve a film-forming speed that can ensure sufficient productivity in industrial production. By employing the compositions of the present disclosure, in addition to the effect of increasing the reaction rate, a uniform thin film can be formed similarly to when the precursor of silane compound 1 is employed alone because the structures of each precursor are similar.

### BRIEF DESCRIPTION OF THE DRAWINGS

FIG. 1 is a schematic sectional view of a CVD precursor supply container that can be used in one embodiment of the present invention.

FIG. 2 is a FID chart of Composition C-1 before decomposition in the Example of Embodiment 1-1.

FIG. 3 is a FID chart of Composition C-1 after decomposition in the Example of Embodiment 1-1.

FIG. 4 is a chart showing the results of simultaneous differential thermal gravimetric analysis of Composition C-1 in the Example of Embodiment 1-1.

FIG. 5 is Table 1 from the Examples showing a summary of silane compositions according to aspects of the disclosure.

FIG. 6 is Table 4 from the Examples showing a summary of silane compositions according to aspects of the disclosure.

### DETAILED DESCRIPTION OF THE INVENTION

The present invention will be described below based on the examples of embodiments for carrying out the invention. However, the present invention is not limited to the examples of embodiments that will be described below.

Furthermore, in this specification, when “X to Y” (where X and Y are arbitrary numbers) is expressed, unless otherwise specified, this includes the meaning of “at least X to at most Y” as well as the meaning of “preferably greater than X” or “preferably less than Y.”

In addition, when “X or more” (where X is an arbitrary number) or “Y or less” (where Y is an arbitrary number) is expressed, this includes the meaning of “preferably greater than X” or “preferably less than Y.”

Furthermore, “X and/or Y (where X and Y are arbitrary components)” means at least one of X and Y, and can mean three possibilities: only X, only Y, or both X and Y.

Regarding the numerical ranges described step-by-step in this document, the upper or lower limit of a given stage's numerical range can be freely combined with the upper or lower limit of another stage's numerical range. Additionally, in the numerical ranges described in this document, the upper or lower limit of the numerical range can be replaced with the values shown in the example of embodiment.

Unless otherwise stated, any numerical value referring to weight percentages, temperatures, flow rates, pressures, etc. (but not GC area percentages) is to be understood as being modified in all instances by the term “about.” Thus, a numerical value typically includes ±10% of the recited value. For example, the recitation of a temperature such as “10° C.” or “about 10° C.” includes 9° C. and 11° C. and all temperatures there between.

All numerical ranges expressed in this disclosure expressly encompass all possible subranges, all individual numerical values within that range, including integers within such ranges and fractions and decimal amounts of the values unless the context clearly indicates otherwise.

Below, the composition containing silane compounds according to one example of an embodiment of the present disclosure (hereinafter referred to as “the composition”) will be described in detail. This composition can be used, for example, as a precursor for chemical vapor deposition (CVD) or atomic layer deposition (ALD). In this composition, the content of components other than Silane compounds 1, 2, 3, 4, and 5 described below is preferably 10% or less by weight relative to the total weight of the composition, and more preferably 5% or less by weight. In this composition, the content of the components of Silane compounds 1, 2, 3, 4, and 5 described below is preferably 90% or more by weight relative to the total weight of the composition, and more preferably 95% or more by weight.

### Silane Compounds

The silane compounds of the present disclosure may be used as precursors for CVD or ALD, together with steam, oxygen, ozone, or oxidizing agents such as hydrogen peroxide, or together with reducing agents such as hydrogen or ammonia in order to adjust the oxidation process and control the growth characteristics of the film. In this case, the necessary performance as an interlayer insulating film may be exhibited as a result of the appropriate reactions and cross-linking primarily by the alkoxy groups within the silane compounds.

### Silane Compound 1

The main component of this composition, Silane compound 1, has formula (1):

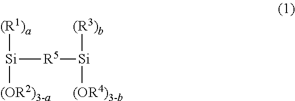

In formula (1), R¹ to R⁴ represent the same or different hydrocarbon groups having 1 to 10 carbon atoms, a and b represent the same or different integers of 0 to 3, a+b is an integer of 5 or less, and R⁵ represents a hydrocarbon group with 1 to 6 carbon atoms. Silane compound 1 has active groups such as OR² or OR⁴ as shown in formula (1), which provide the desired performance.

The number of carbon atoms in R¹ to R⁴ is typically 1 to 10, considering the deposition rate in CVD or ALD, but 1 to 6 carbons is preferred from the viewpoint of mechanical properties after film formation, and 1 to 2 carbons is further preferred from the viewpoint of deposition rate.

R¹ to R⁴ can be, for example, alkyl groups such as, without limitation, methyl, ethyl, propyl, isopropyl, butyl, isobutyl, sec-butyl, t-butyl, pentyl, hexyl, cyclopentyl, or cyclohexyl; aromatic hydrocarbon groups such as phenyl, tolyl, or benzyl; or alkenyl groups such as vinyl, 1-propenyl, allyl, or 3-butenyl. From the viewpoint of the mechanical properties after film formation, methyl, ethyl, vinyl, propyl, allyl, isopropyl, butyl, isobutyl, sec-butyl, and t-butyl groups are preferred, while from the viewpoint of film formation speed, alkyl groups with 1 to 4 carbon atoms such as methyl, ethyl, propyl, and isopropyl are more preferred. It is even more preferable to use methyl, ethyl, and propyl groups, with methyl groups being particularly preferred.

R¹ to R⁴ can all be the same or different from each other, but from the viewpoint of the ease of manufacturing Silane compound 1, it is preferable for R¹ and R³ to be the same, and for R² and R⁴ to be the same, and it is particularly preferable for R¹ to R⁴ to all be the same.

Because the decomposition reactivity tends to increase when the hydrocarbon groups R² and R⁴ are methyl groups, these substituents are preferable when the composition is used for injection type CVD or ALD methods.

Examples of R⁵ include, for example, saturated hydrocarbon groups such as a methylene group, ethylene group, propylene group, butylene group, and aromatic hydrocarbon groups such as a phenylene group. A saturated hydrocarbon group containing 1 to 2 carbon atoms, that is, a methylene group or an ethylene group, is more preferable, and a methylene group is particularly preferable.

In formula (1), a and b are integers ranging from 0 to 3, and may be the same or different. From the viewpoint of film deposition rate and mechanical properties (hardness, elastic modulus, etc.) after film deposition, it is preferable that a and b are the same or different integers ranging from 0 to 2. From the viewpoint of the balance between a low dielectric constant and mechanical properties, it is preferable for both a and b to be 2 or 1, and it is particularly preferable for both to be 1. When a and b are both 3, there are no active groups, and it may be difficult to form chemical bonds with adjacent molecules. Therefore, it is preferable that at least one of a and b is less than 3, and that a+b is an integer of 5 or less. As a+b, it is preferable that the integer ranges from 0 to 4, and it is even more preferable for the integer to range from 2 to 4. From the viewpoint of the film deposition rate and mechanical properties (hardness, elastic modulus, etc.) after film deposition, it is preferable that a=b.

The molecular weight of Silane compound 1 is preferably 160 or more, more preferably 170 or more, and even more preferably 180 or more. Further, it is preferable for the molecular weight to be 400 or less, even more preferable for it to be 300 or less, and further preferable for it to be 250 or less. If the molecular weight of Silane compound 1 is equal to or greater than the lower limit noted above, it tends to have a moderate vapor pressure that is easy to handle as a precursor for CVD or ALD, thereby improving the thermal stability. If the molecular weight of Silane compound 1 is below the upper limit, it tends to have sufficient volatility to reach the substrate in CVD or ALD. The lower and upper limits of the molecular weight of Silane compound 1 may be arbitrarily combined, for example, 160 to 400, 170 to 300, or 180 to 250.

### Silane Compound 2

In some embodiments, the amount of Silane compound 2 having formula (2) may be controlled or adjusted.

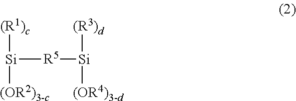

In formula (2), c and d represent the same or different integers of 0 to 3, the sum of c and d is greater than the sum of a and b in formula (1), and R¹ to R⁵ are as defined in formula (1) and may be the same possible and preferred groups as described above.

From the viewpoint of balancing film deposition rate and mechanical strength, as well as to ensure uniform mixing, it is preferable for the sum of c and d to be greater than the sum of a and b in formula (1). From the viewpoint of film deposition rate, it is preferable for c and d to be the same or different integers from 0 to 2, and it is particularly preferable that c is 2 and dis 1, or c is 1 and dis 2.

It is preferable that Silane compound 1 and Silane compound 2 have similar chemical structures in order to facilitate uniform mixing from the viewpoint of reaction rate and film quality. Therefore, it is preferable for the difference between the sum of c and d in formula (2) and the sum of a and b in formula (1) to be 3 or less, more preferably 2 or less, and particularly preferably 1. Also, it is preferable that a and b in formula (1) are the same or different integers from 0 to 2, and that c and d in formula (2) are the same or different integers from 0 to 2.

The molecular weight of Silane compound 2 is preferably 160 or more, more preferably 170 or more, and even more preferably 180 or more. Further, it is preferable for the molecular weight to be 400 or less, even more preferably 300 or less, and further preferably 250 or less. When the molecular weight of Silane compound 2 is equal to or greater than the lower limit, it tends to improve the thermal stability of the precursor composition. If the molecular weight of Silane compound 2 is below the upper limit, it tends to have sufficient volatility to reach the substrate when the composition is used in CVD. The lower and upper limits of the molecular weight of Silane compound 2 can be arbitrarily combined, for example, 160 to 400, 170 to 300, or 180 to 250.

The difference between the molecular weight of Silane compound 1 and the molecular weight of Silane compound 2 is preferably 40 or less from the viewpoint of uniform film formation, more preferably 30 or less, and particularly preferably 20 or less.

### Silane Compound 3

In some embodiments, the amount of Silane compound 3 having formula (3) may be controlled or adjusted.

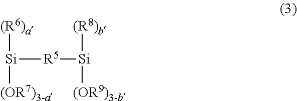

In formula (3), R⁶ to R⁹ represent the same or different hydrocarbon groups with 1 to 10 carbon atoms, and a′ and b′ represent the same or different integers from 0 to 3. R⁶ to R⁹ can be the same as the hydrocarbon groups R¹ to R⁴ in Silane compound 1.

Further, a′ and b′ represent the same or different integers from 0 to 3, and from the viewpoint of film formation speed, a′ and b′ are preferably the same or different integers from 0 to 2. From the viewpoint of uniform mixing between Silane compound 1 and Silane compound 3, it is preferable that a=a′ and b=b′. From the viewpoint of the film deposition rate and mechanical properties after film deposition, it is preferable that a′=b′.

The molecular weight of Silane compound 3 is preferably 170 or more, more preferably 180 or more, and even more preferably 190 or more. Further, it is preferable for the molecular weight to be 400 or less, even more preferably 300 or less, and further preferably 260 or less. When the molecular weight of Silane compound 3 is equal to or greater than the lower limit, it tends to improve the thermal stability of the precursor composition. If the molecular weight of Silane compound 3 is below the upper limit, it tends to have sufficient volatility to reach the substrate when the composition is used in CVD. The lower and upper limits of the molecular weight of Silane compound 3 can be arbitrarily combined, for example, 170 to 400, 180 to 300, or 190 to 260.

The difference between the molecular weight of Silane compound 1 and the molecular weight of Silane compound 3 is preferably 30 or less from the viewpoint of uniform film formation, more preferably 20 or less, and particularly preferably 10 or less.

### Silane Compound 4

In some embodiments, the amount of Silane compound 4 having formula (4) may be controlled or adjusted. Silane compound 4 is presumed to be generated when Silane compound 1 reacts with an active species such as water, causing partial hydrolysis of the alkoxy group.

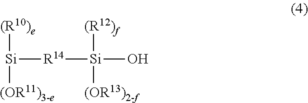

In formula (4), R¹⁰ to R¹³ represent the same or different hydrocarbon groups with 1 to 10 carbon atoms, e is an integer of 0 to 3, f is an integer of 0 to 2, and R¹⁴ represents a hydrocarbon group with 1 to 6 carbon atoms. R¹⁰ to R¹³ and R¹⁴ can be the same groups as those mentioned for Silane compound 1.

The molecular weight of Silane compound 4 is preferably 170 or more, more preferably 180 or more, and even more preferably 190 or more. Further, it is preferable for the molecular weight to be 400 or less, even more preferably 300 or less, and further preferably 250 or less. When the molecular weight of Silane compound 4 is equal to or greater than the lower limit, it tends to improve the thermal stability of the precursor composition. If the molecular weight of Silane compound 4 is below the upper limit, it tends to have sufficient volatility to reach the substrate when the composition is used in CVD. The lower and upper limits of the molecular weight of Silane compound 4 can be arbitrarily combined, for example, 170 to 400, 180 to 300, or 190 to 250.

### Silane Compound 5

In some embodiments, the amount of Silane compound 5 having formula (5) may be controlled or adjusted.

Silane compound 5 is presumed to be generated by the dehydration and condensation of the two OH groups of Silane compound 4.

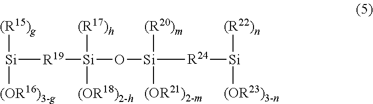

In formula (5), R¹⁵ to R¹⁸ and R²⁰ to R²³ represent the same or different hydrocarbon groups having 1 to 10 carbon atoms, g and n represent the same or different integers of 0 to 3, h and m represent the same or different integers of 0 to 2, and R¹⁹ and R²⁴ represent the same or different hydrocarbon groups having 1 to 6 carbon atoms.

For R¹⁵ to R¹⁸, R²⁰ to R²³, and R¹⁹ and R²⁴, the same groups as those in Silane compound 1 can be used. The molecular weight of Silane compound 5 is preferably 250 or more, more preferably 300 or more, and even more preferably 350 or more. Further, it is preferable for the molecular weight to be 700 or less, even more preferably 600 or less, and further preferably 500 or less. When the molecular weight of Silane compound 5 is equal to or greater than the lower limit, it tends to improve the thermal stability of the precursor composition. If the molecular weight of Silane compound 5 is below the upper limit, it tends to have sufficient volatility to reach the substrate when the composition is used in CVD. The lower and upper limits of the molecular weight of Silane compound 5 can be arbitrarily combined, for example, 250 to 700, 300 to 600, or 350 to 500.

### COMPOSITION EMBODIMENTS

The embodiments of combining Silane compound 1 with Silane compound 2 and/or Silane compound 3 may be classified into the following Compositions A to C. Another embodiment is Composition D.

### Embodiment 1: Composition A: A Composition Containing Silane Compound 1 and Silane Compound 2

Composition A contains Silane compound 1 and Silane compound 2, and the content of Silane compound 1, as calculated from the area percentage in gas chromatography, is 95.0% or higher, the content of Silane compound 2 is 0.05 to 5.0%, and the content of Silane compound 3 is less than 0.01%.

### Embodiment 2: Composition B: A Composition Containing Silane Compound 1 and Silane Compound 3

Composition B contains Silane compound 1 and Silane compound 3, and the content of Silane compound 1, as calculated from the area percentage in gas chromatography, is 90.0% or higher, the content of Silane compound 2 is less than 0.01%, and the content of Silane compound 3 is 0.80 to 10.0%.

### Embodiment 3: Composition C: A Composition Containing Silane Compound 1, Silane Compound 2, and Silane Compound 3

Composition C contains Silane compound 1, Silane compound 2, and Silane compound 3, and the content of Silane compound 1, as calculated from the area percentage in gas chromatography, is 95.0% or higher, the content of Silane compound 2 is 0.05 to 2.0%, and the content of Silane compound 3 is 0.05 to 2.0%.

### Embodiment 4: Composition D: A Composition Containing Silane Compound 1 and Silane Compound 5

Composition C contains Silane compound 1 and Silane compound 5, and the content of Silane compound 1, as calculated from the area percentage in gas chromatography, is 95.0% or higher, the content of Silane compound 2 is less than 0.01%, the content of Silane compound 3 is less than 0.01%, the content of Silane compound 5 is 0.05 to 2.0%, and the chlorine atom content is 9 mass ppm or less.

Thus, Composition A of Embodiment 1 does not substantially contain Silane compound 3, and Composition B of Embodiment 2 does not substantially contain Silane compound 2. In Embodiment 4, Composition D does not substantially contain Silane compound 2 or Silane compound 3.

In each of these embodiments, Silane compound 4 is not necessary, but it can be included if desired.

The method for incorporating Silane compound 2 and/or Silane compound 3 into Silane compound 1 can be any of the following: mixing Silane compound 1 and Silane compound 2 and/or Silane compound 3 that have been prepared separately, mixing Silane compound 2 and/or Silane compound 3 during the synthesis of Silane compound 1, or generating Silane compound 2 and/or Silane compound 3 as a side reaction product during synthesis.

Silane compound 4 and Silane compound 5 may be intentionally added, but Silane compound 4 may also be generated during the storage of Silane compound 1 due to hydrolysis, and Silane compound 5 may also be generated by the dimerization of Silane compound 4.

The contents (%) of the silane compounds in the composition can be quantified with high sensitivity and accuracy by separating the composition using gas chromatography and using a Flame Ionization Detector (FID) as the detector. For example, detection of 0.01% is also possible.

If no peak for a silane compound is detected by this analytical method, the content of the corresponding silane compound can be concluded to be less than 0.01%.

This composition may be used as a precursor for CVD or ALD, and preferably does not contain any solvent. When the composition does not contain any solvent, it will be possible to analyze the composition directly using the above-noted gas chromatography without any prior treatment. Note that ‘substantially free of solvent’ means that the content of solvent in the composition when converted from the area percentage in gas chromatography is less than 0.01%.

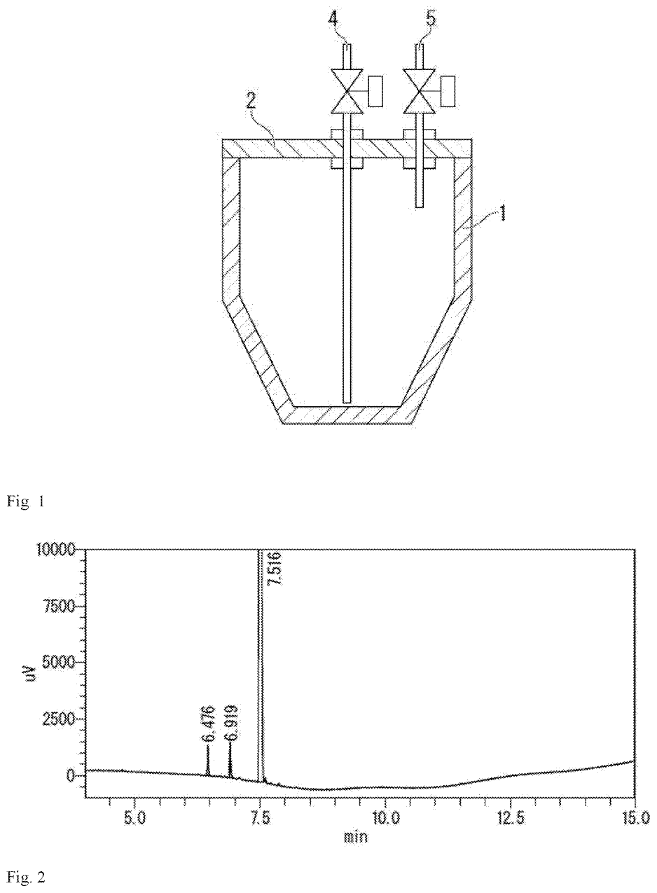

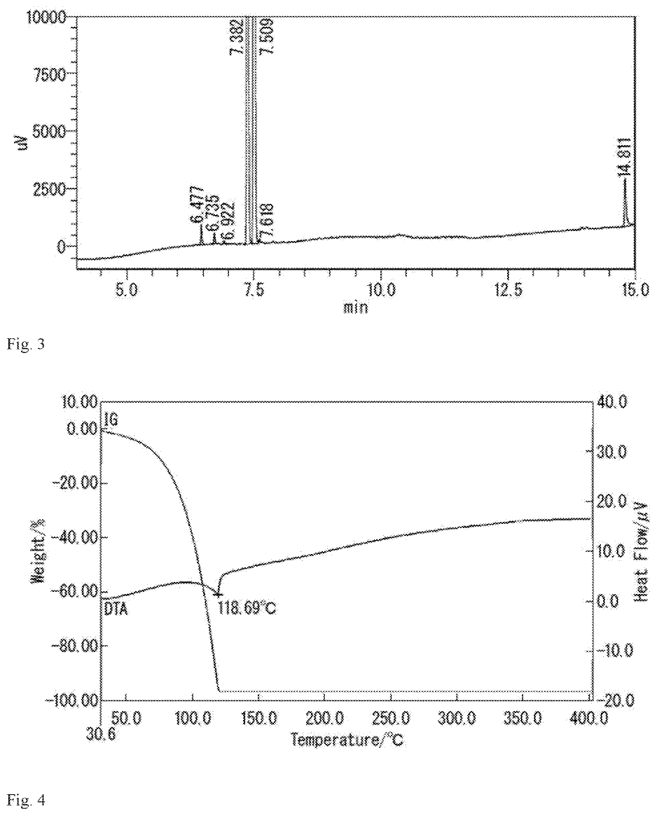

As an example, first, the area of each peak in the chart obtained using FID (see FIG. 2 and FIG. 3 for examples) is calculated. At that time, it is possible to identify the chemical structure of the compound corresponding to each peak by using a separate method such as mass spectrometry. Next, the content is calculated as a percentage by taking the total sum of the area integration values of the peaks of all of the compounds containing the silane atoms that were observed as the denominator, and using the area integration value of the peak of the target silane compound as the numerator.

According to this calculation method, only the compounds containing silane atoms are subject to the calculation of the content percentage (%), and solvents, additives, and impurities that do not contain silane atoms are not subject to this calculation.

Moreover, because the sensitivity of FID varies depending on the compound in the above-mentioned quantification method based on the area ratio, it does not result in a strict assay. However, amongst compounds with similar chemical structures, the sensitivity factor values of the detector can be estimated to be close. Therefore, in the present disclosure, the area ratio obtained by the detector (FID as an example) for each compound separated by gas chromatography is defined as the quantitative ratio of the compound.

### Example of Embodiment 1

The content of Silane compound 1 in Composition A, as calculated from the area percentage in gas chromatography, should be 95.0% or more. From the viewpoint of uniform film quality after film formation, a content of 96.0% or more is more preferable, while a content of 98.0% or more is even more preferable, and a content of 99.0% or more is particularly preferable. On the other hand, when the content of Silane compound 1 is 100%, there is room for improvement in the film deposition rate, so the content of Silane compound 1 in Composition A should be 99.99% or less, and from the viewpoint of balancing the film deposition rate and the uniform film quality after deposition, a content of 99.98% or less is more preferable, while a content of 99.9% or less is even more preferable, a content of 99.7% or less is even more preferable, and a content of 99.5% or less is particularly preferable. The lower limit and upper limit of the content of Silane compound 1 in the above Composition A can be arbitrarily combined, for example, 95.0 to 99.99%, 95.0 to 99.98%, 96.0 to 99.9%, 98.0 to 99.9%, 98.0 to 99.7%, or 99.0 to 99.5%.

From the standpoint of reactivity, the content of Silane compound 2 in Composition A, as calculated from the area percentage in gas chromatography, should be 0.05% or more, although 0.07% or more is preferable, 0.1% or more is even more preferable, 0.3% or more is even more preferable, and 0.4% or more is particularly preferable. On the other hand, from the perspective of the film properties, the content of Silane compound 2 in Composition A should be 5.0% or less, although 3.0% or less is even more preferable, 2.0% or less is even more preferable, and 1.0% or less is particularly preferable. The lower limit and upper limit of the content of Silane compound 2 in the Composition A can be arbitrarily combined, for example, 0.05 to 5.0%, or 0.07 to 5.0%, 0.1 to 3.0%, 0.1 to 2.0%, 0.3 to 2.0%, or 0.4 to 1.0%.

The content of Silane compound 3 in Composition A, as calculated from the area percentage in gas chromatography, should be less than 0.01%. In other words, this means that Silane compound 3 is substantially not included in Composition A, and the lower limit of its content is 0%.

### Example of Embodiment 2

The content of Silane compound 1 in Composition B, as calculated from the area percentage in gas chromatography, should be 90.0% or more. From the viewpoint of uniform film quality after film formation, a content of 92.0% or more is more preferable, while a content of 93.0% or more is even more preferable, and a content of 94.0% or more is particularly preferable. On the other hand, when the content of Silane compound 1 is 100%, there is room for improvement in the film deposition rate, so the content of Silane compound 1 in Composition B should be 99.5% or less, and from the viewpoint of balancing the film deposition rate and the uniform film quality after deposition, a content of 99.2% or less is even more preferable, a content of 99.0% or less is even more preferable, and a content of 98.5% or less is most preferable. The lower limit and upper limit of the content of Silane compound 1 in the above Composition B can be arbitrarily combined, for example, 90.0 to 99.5%, 92.0 to 99.5%, 93.0 to 99.5%, 93.0 to 99.2%, 93.0 to 99.0%, or 94.0 to 98.5%.

From the standpoint of reactivity, the content of Silane compound 3 in Composition B, as calculated from the area percentage in gas chromatography, should be 0.80% or more, although 0.90% or more is more preferable, a content of 1.0% or more is even more preferable, and a content of 1.5% or more is particularly preferable. On the other hand, from the perspective of the film properties, the content of Silane compound 3 in Composition B should be 10.0% or less, although 9.0% or less is more preferable, while a content of 8.0% or less is even more preferable, and 5.0% or less is particularly preferable. The lower limit and upper limit of the content of Silane compound 3 in the above Composition B can be arbitrarily combined, for example, 0.80 to 10.0%, 0.80 to 9.0%, 0.80 to 8.0%, 0.90 to 8.0%, 0.90 to 5.0%, 1.0 to 5.0%, or 1.5 to 5.0%.

The content of Silane compound 2 in Composition B, as calculated from the area percentage in gas chromatography, should be less than 0.01%. In other words, this means that Silane compound 2 is substantially not included in Composition B, and the lower limit of its content is 0%.

### Example of Embodiment 3

The content of Silane compound 1 in Composition C, as calculated from the area percentage in gas chromatography, should be 95.0% or more. From the viewpoint of uniform film quality after film formation, a content of 96.0% or more is more preferable, while a content of 97.0% or more is even more preferable, a content of 98.0% or more is even more preferable, a content of 99.0% is even more preferable, and a content of 99.6% or more is particularly preferable. On the other hand, when the content of Silane compound 1 is 100%, there is room for improvement in the film deposition rate, so the content of Silane compound 1 in Composition C should be 99.98% or less, and from the viewpoint of balancing the film deposition rate and the uniform film quality after deposition, a content of 99.96% or less is more preferable, while a content of 99.90% or less is even more preferable, and a content of 99.84% or less is particularly preferable. The lower limit and upper limit of the content of Silane compound 1 in the above Composition C can be arbitrarily combined, for example, 95.0 to 99.98%, 96.0 to 99.98%, 97.0 to 99.96%, 98.0 to 99.96%, 99.0 to 99.90%, or 99.6 to 99.84%.

The content of Silane compound 2 in Composition C, as calculated from the area percentage in gas chromatography, should be 0.05% or more, although 0.06% or more is preferable, 0.07% or more is even more preferable, and 0.08% or more is particularly preferable. On the other hand, from the perspective of uniform film properties, the content of Silane compound 2 in Composition C should be 2.0% or less, although 1.5% or less is more preferable, 1.0% or less is even more preferable, 0.50% or less is even more preferable, and a content of 0.20% or less is particularly preferable. The lower limit and upper limit of the content of Silane compound 2 in the above Composition C can be arbitrarily combined, for example, 0.05 to 2.0%, 0.05 to 1.5%, 0.06 to 1.0%, 0.07 to 0.50%, or 0.08 to 0.20%.

The content of Silane compound 3 in Composition C, as calculated from the area percentage in gas chromatography, should be 0.05% or more, although 0.06% or more is preferable, 0.07% or more is even more preferable, and 0.08% or more is particularly preferable. On the other hand, from the perspective of uniform film properties, the content of Silane compound 3 in Composition C should be 2.0% or less, although 1.5% or less is more preferable, 1.0% or less is even more preferable, 0.50% or less is even more preferable, and a content of 0.20% or less is particularly preferable. The lower limit and upper limit of the content of Silane compound 3 in the above Composition C can be arbitrarily combined, for example, 0.05 to 2.0%, 0.05 to 1.5%, 0.06 to 1.0%, 0.07 to 0.50%, or 0.08 to 0.20%.

Furthermore, Composition C, which contains three types of silane compounds (Silane compound 1, Silane compound 2, and Silane compound 3), exhibits an equivalent or better effect with lower contents of Silane compound 2 and Silane compound 3 when compared to Composition A, which contains Silane compound 1 and Silane compound 2, or Composition B, which contains Silane compound 1 and Silane compound 3. Therefore, Composition C boasts a synergistic effect.

When Silane compound 1 is used alone, there is room for improvement in the film formation speed, and there is a problem of low productivity in film formation. While the cause is unclear, due to the uniform molecules and low dielectric constant, it is thought that the affinity is low, such as molecular-level dipole interactions with the reaction gas, resulting in difficulties in progressing the reaction. On the other hand, by blending certain proportions of Silane compounds 2, 3, 4, and 5, which have a chemical structure similar to Silane compound 1 but with different molecular dipoles, these compounds can serve as the starting point for reaction with the reaction gas, and the reaction is expected to proceed smoothly. In this case, the deposition rate is less likely to slow down if the reaction rate is not too low, and the industrial productivity is less likely to worsen. Conversely, if the temperature is not too high, film deposition tends to occur uniformly, resulting in a uniform film quality. Furthermore, by incorporating Silane compound 2, Silane compound 3, Silane compound 4, and Silane compound 5, which have adjusted proportions relative to Silane compound 1, there is a tendency for suppression of the localized crystallization of Silane compound 1, thereby facilitating the achievement of uniform film quality.

### Example of Embodiment 4

The content of Silane compound 1 in Composition D, as calculated from the area percentage in gas chromatography, should be 95.0% or more. From the viewpoint of uniform film quality after film formation, a content of 96.0% or more is more preferable, while a content of 98.0% or more is even more preferable, and a content of 99.0% or more is particularly preferable. On the other hand, when the content of Silane compound 1 is 100%, there is room for improvement in the film deposition rate, so the content of Silane compound 1 in Composition A should be 99.99% or less, and from the viewpoint of balancing the film deposition rate and the uniform film quality after deposition, a content of 99.98% or less is more preferable, while a content of 99.9% or less is even more preferable, a content of 99.7% or less is even more preferable, and a content of 99.5% or less is particularly preferable. The lower limit and upper limit of the content of Silane compound 1 in the above Composition D can be arbitrarily combined, for example, 95.0 to 99.99%, 95.0 to 99.98%, 96.0 to 99.9%, 98.0 to 99.9%, 98.0 to 99.7%, or 99.0 to 99.5%.

The content of Silane compound 2 in Composition D, as calculated from the area percentage in gas chromatography, should be less than 0.01%. In other words, this means that Silane compound 2 is substantially not included in Composition D, and the lower limit of its content is 0%.

The content of Silane compound 3 in Composition D, as calculated from the area percentage in gas chromatography, should be less than 0.01%. In other words, this means that Silane compound 3 is substantially not included in Composition D, and the lower limit of its content is 0%.

The content of Silane compound 5 in Composition D, as calculated from the area percentage in gas chromatography, should be 0.05% or more, although 0.10% or more is even more preferable, and 0.15% or more is particularly preferable. On the other hand, the content of Silane compound 5 in Composition D should be 2.0% or less, although 1.5% or less is more preferable, 1.0% or less is even more preferable, 0.50% or less is even more preferable, and a content of 0.40% or less is particularly preferable. The lower limit and upper limit of the content of Silane compound 5 in the above Composition D can be arbitrarily combined, for example, 0.05 to 2.0%, 0.05 to 1.0%, 0.10 to 2.0%, 0.10 to 0.50%, 0.10 to 0.40%, 0.15 to 2.0%, or 0.15 to 1.5%.

The chlorine atom content in Composition D should be 9 mass ppm or less, although 7 mass ppm or less is preferable, 5 mass ppm or less is more preferable, 4 mass ppm or less is even more preferable, and 3 mass ppm or less is particularly preferable. The lower limit value for the chlorine atom content is preferably 0 mass ppm.

In the compositions of Embodiments 1 to 4, Silane compound 4 is not a necessary component. However, Silane compound 4 is an intermediate that necessarily occurs when Silane compound 1 is reacted via CVD or ALD, and it can be present within a certain range. More specifically, Silane compound 4 in this composition, as calculated from the area percentage in gas chromatography, may be present in an amount exceeding 0%, although 0.03% or more is acceptable, and there are instances in which 0.05% or more is acceptable, while there are also instances in which 0.06% or more is acceptable. On the other hand, in order to suppress the tendency for Silane compound 4 to dimerize and form Silane compound 5, the upper limit should be 0.30% or less, although 0.20% or less is even more preferable, and 0.10% or less is particularly preferable. The lower and upper limits of the content of Silane compound 4 in the compositions of Embodiments 1 to 4 can be arbitrarily combined. For example, when the compositions of Embodiments 1 to 4 include Silane compound 4, the content may be more than 0.0% and 0.30% or less, 0.03 to 0.30%, 0.03 to 0.20%, 0.05 to 0.30%, 0.05 to 0.20%, or 0.03 to 0.10%.

### Metal Impurities

The metal content in the compositions described herein refers to the content of metal and/or metalloid elements contained as impurities in the composition, and may be expressed in units such as mass %, mass ppm, and mass ppb. There are no particular restrictions on the target metal elements, but examples include Ag, Al, Au, Ba, Ca, Cd, Co, Cr, Cu, Fe, Hf, In, K, Li, Mg, Mn, Mo, Na, Ni, Pb, W, Zn, Zr, and Sn. In particular, in cutting-edge fine semiconductor processes (such as fabrication of fine wiring with a width of less than 100 nm or EUV lithography systems), trace metal impurities in semiconductor materials are likely to cause pattern defects, short circuits or corrosion of metal wiring, increased out-gassing, and other issues, which can lead to a decline in performance and yield. Therefore, stricter control is required.

The metal content in the compositions described herein is preferably 10 mass ppm or less for each metal, although 1 mass ppm or less is more preferable, 100 mass ppb or less is even more preferable, 50 mass ppb or less is even more preferable, 30 mass ppb or less is particularly preferable, and 10 mass ppb or less is especially preferable. In particular, for cutting-edge fine semiconductor processes (such as fabrication of fine wiring with a width of less than 100 nm or EUV systems), the metal content in the compositions should be 10 mass ppb or less for each metal, although 5 mass ppb or less is preferable, and 1 mass ppb or less is even more preferable.

### Measurement of the Metal Content

There are no particular restrictions on the method of measuring the metal content, but it is preferable for the method to have a lower limit for detection sensitivity of 10 mass ppb or less, or more preferably 1 mass ppb or less, for each metal element. Specific methods include those shown in the examples, and these measurements are typically carried out using a combination of pretreatment methods and analytical methods, such as those described below.

As the pretreatment method, it is preferable to recover the metal elements from the composition to be analyzed with a high recovery rate, high precision, and high reproducibility. Examples of such methods include combustion absorption and acid decomposition methods. As the analytical method, in order to achieve the detection sensitivity mentioned above, methods such as quantification by ion chromatography (IC) or inductively-coupled plasma mass spectrometry (ICP-MASS) can be used. By appropriately combining these pretreatment and analytical methods, it is possible to analyze the metal content within the composition.

### Methods for Reducing Metal Elements

Methods for reducing metal elements in the composition include (1) reducing metal elements derived from raw materials, (2) removing metal elements by purifying the composition, and (3) reducing the contamination of metal elements from the equipment or environment that is used. Each method will be explained below.

(1) Method of Reducing Metal Elements Derived from Raw Materials

While it is possible to use raw materials containing metals in their structure to form the silane compounds that make up the compositions described herein, it is preferable to use raw materials with low levels of metal elements other than those present within the structure. More specifically, the content of each metal element other than in the structure of the raw material should be less than 1% by weight, although 0.5% by weight or less is more preferable, 0.1% by weight or less is even more preferable, and 0.01% by weight or less is even more preferable. A level of 10 mass ppm or less is even more preferable, while 1 mass ppm or less is even more preferable, 100 mass ppb or less is further preferable, and 10 mass ppb or less is particularly preferable. Particularly in applications when the composition is a film-forming material for cutting-edge semiconductor processes, it is preferable to control the content of metals other than those contained within the chemical compounds in the raw material in order to stably manufacture a homogeneous material, and it is preferable for this content to be 10 mass ppb or less, and more preferably, 1 mass ppb or less.

### (2) Method of Removing Metal Elements by Purifying the Composition

The method of reducing metal elements within the composition by purification may be carried out by combining various purification methods. Examples of this method include filtering insoluble matter, liquid separation (using ultrapure water, etc.), column chromatography, removal using reagents or chelating agents, adsorption onto resins, and distillation purification. On the other hand, when silane compounds show reactivity towards water or functional groups, the purification methods for these compounds are limited, and distillation purification is preferable. In the case of distillation purification, a distillation method using a distillation column can be applied. A distillation column using SUS structured packing is preferable because trace metal impurities are efficiently adsorbed onto the SUS structured packing, promoting separation. On the other hand, in order to reduce the metal components that may leach out from the SUS during distillation, it is preferable to remove the initial fraction in a short time at a low reflux ratio, and then to set the reflux ratio to obtain the main fraction for obtaining high-purity silane compounds.

(3) Method to Reduce the Contamination of Metal Elements from the Equipment (Devices, Containers, Etc.) or the Environment that is Used

When removing metal components in distillation, it is necessary to prevent the contamination of metals from the equipment used for distillation. Silane compounds, which become liquid and gaseous at high temperatures during distillation, may leach metal components or may cause metal leaching due to the oxidation-reduction properties of silane compounds, which can corrode metal equipment. Therefore, more careful attention should be paid to metal leaching and contamination from the equipment and apparatus used as compared to the distillation of ordinary organic compounds. When using SUS equipment, it is preferable to use SUS with high corrosion resistance or SUS with surface corrosion-resistant treatment. More specifically, SUS 316 and SUS 304 are preferred, and materials with corrosion-resistant surface treatment are even more preferable. When using a SUS or glass equipment and apparatus, it is preferable to perform reflux washing with a solvent containing alcohol (such as methanol, ethanol, or isopropanol) under sufficient reflux conditions. It is particularly preferable to use SUS equipment, and when using such equipment, it is even more preferable to remove a wider range of impurities, including lipophilic and hydrophilic metal impurities, by combining cleaning with alcohol solvents with cleaning with other non-protonic organic solvents (such as acetone, heptane, or toluene, etc.). It is also preferable for the container used to fill the obtained silane compound to be a well-cleaned container, and it is particularly preferable that the container is cleaned with ultrapure water and dried.

In addition, metal atoms may be introduced from the environment, such as from the human body, protective gloves, or the atmosphere. In order to prevent these impurities, it is preferable to fill the silane compound directly into the container without exposing it to the atmosphere after distillation. It is also preferable to conduct manufacturing under conditions in which metal elements are reduced, such as within a clean room where the distillation equipment is located.

### Halogen Impurities

The halogen content in the compositions described herein refers to the content of halogen atoms (F, Cl, Br, I) in all of the silane compounds contained in the composition, which may be expressed in units such as mass %, mass ppm, or mass ppb. In particular, in cutting-edge fine semiconductor processes (such as fabrication of fine wiring with a width of less than 100 nm or EUV lithography systems), trace halogen impurities in semiconductor materials are likely to cause pattern defects, short circuits or corrosion of metal wiring, degradation of the substrate surface, and other issues, which can lead to a decline in performance and yield. Therefore, stricter control is required. Regarding the types of compounds containing halogen atoms that may be introduced, various compounds such as organic halogen compounds (compounds with C-halogen bonds) and inorganic halogen compounds (compounds with metal-halogen bonds) can be considered. However, the presence of silane compounds containing Si-halogen bonds, which is a specific challenge in the compositions described herein, may be particularly problematic. More specifically, silane compounds containing Si-halogen bonds exhibit properties similar to those of non-halogenated silane compounds in terms of stability, reactivity, volatility (boiling point), melting point, and solubility in organic solvents, and are often difficult to separate from silane compounds. In other words, even with the halogen reduction techniques that have been implemented in conventional similar semiconductor materials (such as film-forming materials using organic compounds or polymers), it may be difficult to remove these compounds. Even if a composition having high purity silane compounds and a low content of metals other than silane is obtained, the halogen content may not be reduced to the desired level, because trace amounts of silane compounds containing Si-halogen bonds may remain and cannot be removed.

The content of each halogen atom (fluorine atom (F), chlorine atom (CI), bromine atom (Br), and iodine atom (I)) in the compositions described herein is preferably 100 mass ppm or less, although 50 mass ppm or less is more preferable, 30 mass ppm or less is even more preferable, 10 mass ppm or less is further preferable, 9 mass ppm or less is even more preferable, and 5 mass ppm or less is particularly preferable for each halogen atom. In particular, for use in the most advanced fine semiconductor processes (such as fabrication of fine wiring with a width of less than 100 nm or EUV lithography systems), 10 mass ppm or less is preferred, 9 mass ppm or less is more preferred, 5 mass ppm or less is further preferred, and 3 mass ppm or less is particularly preferred.

Particularly with regard to chlorine atoms, there is a high risk of contamination from the raw materials, equipment, and devices used in the production of silane compounds. Chlorine atoms can cause corrosion of semiconductor process equipment, increased out-gassing, pattern defects, short circuits, and corrosion of metal wiring. Therefore, it is preferable to reduce halogen atoms, especially chlorine atoms, to a lower level. From this standpoint, the chlorine atom content that may be detected within this composition is preferably 10 mass ppm or less, although 9 mass ppm or less is more preferable, 7 mass ppm or less is even more preferable, 5 mass ppm or less is even more preferable, 4 mass ppm or less is particularly preferable, and 3 mass ppm or less is especially preferable.

### Measurement of the Halogen Content

There are no particular restrictions on the method for measuring the halogen content, but it is preferable for the method to have a lower limit for detection sensitivity of 3 ppm or less, or more preferably 1 mass ppm, for each halogen atom Specific methods include those shown in the examples, and these measurements are typically carried out using a combination of pretreatment methods and analytical methods, such as those described below. In particular, for detection of trace amounts (at the 10 ppm level, for example) of volatile silane compounds containing Si-halogen bonds, it may be difficult to separate these compounds from other components to be detected using conventional methods such as gas chromatography, which are typically used for purity analysis of silane compounds. Additionally, the detection sensitivity for halogen-containing compounds (because the sensitivity in FID detectors, for instance, is derived from carbon and hydrogen atoms) may be insufficient to detect trace components. Furthermore, when using methods for trace metal analysis or elemental analysis (targeting elements other than halogens, such as carbon, nitrogen, or oxygen), it may be difficult to achieve the appropriate trace detection due to insufficient recovery of the target halogen-containing components during the pre-treatment, decomposition, or absorption processes.

As the pretreatment method, it is preferable to recover the halogen atoms from the composition to be analyzed with high recovery rate, high precision, and high reproducibility. Examples of such methods include combustion absorption and acid decomposition methods. As the analytical method, in order to achieve the detection sensitivity mentioned above, methods such as quantification by ion chromatography (IC) or inductively-coupled plasma mass spectrometry (ICP-MASS) can be used. By appropriately combining these pretreatment and analytical methods, it is possible to analyze the halogen content within the composition. In particular, in order to properly detect and quantify trace halogen components originating from volatile silane compounds, including the aforementioned Si-halogen bonds, it is preferable to use the combustion absorption method, combining the appropriate treatment and absorption methods. Under the appropriate conditions for the measurement of the halogen content, it is preferable to have a lower limit on the detection sensitivity of 10 ppm or less, or more preferably 1 mass ppm, for each halogen atom.

### Methods for Reducing the Halogen Content

The methods for reducing the halogen content in the compositions described herein include: (1) reducing halogen impurities derived from raw materials, (2) removing halogen impurities by purifying compositions containing silane compounds, and (3) reducing the contamination of halogen impurities from the equipment or environment that is used. Each method will be explained below.

(1) Method for Reducing Halogen Impurities Derived from Raw Materials

While it is possible to use raw materials containing halogen in their structure to form the silane compounds, it is preferable to use raw materials containing low levels of halogen elements other than those present within the chemical structure. More specifically, the content of each halogen element other than those in the chemical structure of the raw material should be less than 1% by weight, although 0.5% by weight or less is more preferable, 0.1% by weight or less is even more preferable, and 0.01% by weight or less is even more preferable. Further, a content of 10 mass ppm or less is even more preferable, and a content of 5 mass ppm or less is particularly preferable. Especially in applications when the composition is used as the film-forming material for cutting-edge semiconductor processes, it is preferable to control the content of halogens other than those contained within the chemical compounds of the raw material in order to stably manufacture a homogeneous material, and it is preferable for this content to be 10 mass ppm or less, and more preferably 5 mass ppm or less. In addition, in the final step to obtain the silane compounds, it is preferable to avoid using raw materials that could become halogen impurities (such as compounds with Si-halogen bonds) and that are difficult to separate in the subsequent purification process.

### (2) Method of Removing Halogen Impurities by Purifying a Composition Containing Silane Compounds

Methods for reducing halogen elements in compositions containing silane compounds through purification include various purification methods such as filtering insoluble matter, liquid separation (using ultrapure water, etc.), column chromatography, removal using reagents or chelating agents, adsorption onto resins, and distillation purification. On the other hand, when silane compounds show reactivity towards water or functional groups, the purification methods for these compounds are limited, and distillation purification is preferable. In the case of distillation purification, a distillation method using a distillation column can be applied. In particular, a distillation column using SUS structured packing is preferable because trace halogen impurities (in particular, impurities having an Si-halogen bond, and compounds that can easily react with or attach to the SUS surface) are efficiently adsorbed onto the SUS structured packing, promoting separation. Additionally, in order to efficiently remove halogen impurities during distillation, it is preferable to remove the initial fraction containing low-boiling-point halogen impurities, and then to set the reflux ratio to remove halogen impurities with similar boiling points to obtain a high-purity silane compound.

(3) Method to Reduce the Contamination of Halogen Impurities from the Equipment (Devices, Containers, Etc.) or the Environment that is Used

When removing halogen components during distillation, it is necessary to prevent the contamination of halogens from the equipment used for distillation. In particular, silane compounds that become liquid and gaseous at high temperatures during distillation (especially those with highly reactive Si-halogen bonds) may leach out halogen components contained in the equipment (glass or SUS), requiring more attention to be paid to the leaching and contamination of halogen components from the equipment and devices used than is required in the distillation of ordinary organic compounds. When using SUS equipment, it is preferable to use SUS with high corrosion resistance or SUS with surface corrosion-resistant treatment. More specifically, SUS 316 and SUS 304 are preferred. Materials with corrosion-resistant surface treatments are even more preferable. When using a SUS or glass equipment and apparatus, it is preferable to perform reflux washing with a solvent containing alcohol (such as methanol, ethanol, or isopropanol) under sufficient reflux conditions. It is particularly preferable to use SUS equipment, and when using such equipment, it is even more preferable to remove a wider range of impurities, including lipophilic and hydrophilic halogen impurities, by combining cleaning with alcohol solvents with cleaning with other non-protonic organic solvents (such as acetone, heptane, or toluene, etc.). It is also preferable for the container used to fill the obtained silane compound to be a well-cleaned container, and it is particularly preferable that the container is cleaned with ultrapure water and dried. In addition, halogen impurities may be introduced from the environment, such as from the human body, protective gloves, or the atmosphere. In order to prevent these impurities, it is preferable to fill the silane compound directly into the container without exposing it to the atmosphere after distillation. It is also preferable to conduct manufacturing under conditions in which halogen has been reduced, such as within a clean room where the distillation equipment is located.

### Method of Storing the Composition Containing Silane Compound 1

In order to maintain the high purity of this composition, it is preferable to use a well-sealed container, fill it with an inert gas (such as nitrogen or argon), and store it in a state to ensure that no air and water from the atmosphere can enter. In terms of the specific impact, if, for instance, the composition is stored at room temperature for an extended period of time (such as one month or longer) in a state in which air or water may enter, the above-noted Silane compounds 4 or 5 may be generated as by-products. Additionally, by using a properly sealed container made of the appropriate material, it will be possible to suppress the incorporation of trace metal impurities or halogen impurities from the atmosphere. As a result, it will be possible to prevent the incorporation of the aforementioned trace halogen impurities and metal impurities, and to perform storage while maintaining a low content of these impurities. As for the specific containers for storage, the containers listed in the description of the sealed container described below are preferable.

### Thin Film Manufacturing Method

Thin films may be formed by applying a coating using the compositions described herein as a precursor. The average thickness of the thin film is preferably 500 nm or less. To deal with fine structures, a thickness of 300 nm or less is preferable, 200 nm or less is more preferable, and 100 nm or less is particularly preferable. The lower limit of the average thickness of the thin film is preferably 10 nm or more, although 20 nm or more is more preferable, and 30 nm or more is particularly preferable. The lower and upper limits of the average thickness of the thin film can be arbitrarily combined, for example, 10 to 500 nm, 20 to 300 nm, 20 to 200 nm, or 30 to 100 nm.

The average thickness of the thin film may be measured using methods such as spectroscopic ellipsometry, X-ray reflectivity (XRR), or transmission electron microscopy (TEM). In particular, spectroscopic ellipsometry is non-destructive and highly accurate, making it suitable for measuring thin film thicknesses of 500 nm or less. Moreover, it is preferable to have a high in-plane uniformity of the thin film thickness. For example, in the in-plane thickness uniformity described in the examples below, a value of ±5% or less is preferable, while 3% or less is more preferable, and 1% or less is even more preferable. In particular, when using the plasma CVD or ALD described below, higher film thickness uniformity is required when continuously forming a uniform film using an injection method or the like. For use as a semiconductor insulating film that can withstand post-deposition processes (such as CMP or wiring formation processes), the hardness of the thin film should be 1.0 GPa or greater, although 1.5 GPa or more is even more preferable, 2.0 GPa or greater is preferable, and 2.5 GPa or more is even more preferable. As for the complex modulus of elasticity, 10 GPa or more is preferable, 20 GPa or more is more preferable, and 30 GPa or more is even more preferable.

As a coating method, a dry method may be used, a wet method may be used, or a combination thereof may be used.

Examples of dry methods include, for example, physical vapor deposition (PVD) and chemical vapor deposition (CVD).

Examples of wet methods include, for example, spin coating, spray coating, dip coating, knife-edge coating, and printing methods (for example, ink-jet printing and screen printing). In the case of a wet method, it is preferable to form a thin film by spin coating using the composition.

The coating may be performed once or multiple times. For example, multiple spin coatings may be performed using a wet method, or multiple chemical vapor deposition (CVD) processes may be performed using a dry method. Additionally, spin coating may be followed by chemical vapor deposition using a dry method in order to achieve the desired final coating thickness. Additionally, heat treatment may be applied after each coating step or after multiple coating steps.

The physical vapor deposition (PVD) methods that may be used for forming films of this composition using a dry method include vacuum deposition and sputtering. Chemical vapor deposition (CVD) methods include thermal CVD, plasma CVD, and photo-CVD, as well as atomic layer deposition (ALD). In the case of a dry method, it is preferable to form a thin film using CVD or ALD with this composition.

Plasma CVD (PECVD) is particularly suitable based on the fact that it allows for film formation at low temperatures, boasts a high deposition rate, and may uniformly coat uneven surfaces. PECVD is a method that uses plasma to promote chemical reactions and deposit thin films on substrates, and this method is widely used in semiconductor manufacturing and optical device production. In this method, a reaction gas is introduced into a vacuum chamber, and plasma is generated using a high-frequency power supply or similar device. The active species within the plasma (such as radicals and ions) promote chemical reactions, and thin films are formed on the substrate surface. The deposition rate and film quality will depend on factors such as the plasma density and energy, substrate temperature, and gas flow rate.

The reaction gases that may be used in PECVD include silane (SiH₄), methane (CH₄), nitrous oxide (N₂O), oxygen (O₂), nitrogen (N₂), ammonia (NH₃), and carbon tetrafluoride (CF₄). Amongst these, oxygen is preferred for the purposes of this disclosure.

When depositing films using PECVD, the boiling point of the composition and the weight loss may be used as indicators of achieving uniform films. These parameters may be measured using differential thermal analysis (DTA) and thermogravimetric analysis (TGA) simultaneously, such as with a differential thermal gravimetric analyzer. In this case, in order to ensure uniform film formation, it is preferable for the DTA curve to show simple behavior with a single endothermic peak, at which point the weight decreases by 100%.

### Methods for Transporting the Composition

As a method for transporting the composition, an example is a method that involves vaporizing the composition and then transporting the vaporized composition through a pipeline.

By vaporizing the composition, introducing the vaporized composition into the reaction chamber, and forming a thin film on a substrate in the reaction chamber, a substrate with a thin film can be manufactured.

For example, when forming a thin film using a remote plasma CVD apparatus, the reaction chamber is composed of a plasma generation space and a substrate processing space. After vaporizing the liquid precursor composition of the present disclosure, the vaporized gas is introduced into the substrate processing space via the plasma generation space, and a thin film is formed on the substrate in the substrate processing space. The following describes the details of an example of the process for the transfer and vaporization of the liquid precursor composition.

First, the liquid precursor is contained in a sealed supply container (sealed vessel), and the sealed container is heated to a predetermined temperature in order to increase the vapor pressure of the precursor. The heating temperature may be appropriately set according to the physical properties of the precursor, but generally, a range of 30° C. to 100° C. is preferred. A carrier gas (such as nitrogen or argon) is introduced into the sealed container, and the precursor liquid is vaporized as the carrier gas passes through the liquid surface. When vaporizing the precursor, it is preferable to use reduced pressure conditions in order to increase the vapor pressure. More specifically, in order to sufficiently increase the vapor pressure, the upper limit of pressure should be 10 kPa or less, although 5 kPa or less is preferable, 3 kPa or less is even more preferable, and 1 kPa or less is particularly preferable.

The vaporized precursor is transferred from the sealed container to the reaction chamber of the remote plasma CVD apparatus via heated piping. At this time, the piping must be heated throughout its entire length in order to prevent recondensation of the vaporized gas. The heating temperature should be maintained above the boiling point of the precursor and within a range that prevents thermal decomposition, such as for example, in the range of 50° C. to 150° C. As the heating means, heater tape, jacket heater, or heating chamber may be used, and it is preferable to apply PID (Parameter from Proportional and Integral and Derivative) controllers for temperature control.

There are no particular restrictions on the method and apparatus for vaporizing the precursor as long as the precursor vapor can be stably supplied to the CVD or ALD apparatus (the chamber part in which the film deposition is performed) at an appropriate flow rate and vapor pressure. However, for industrial-scale production, it is preferable to use an injection-type vaporization system that can stably vaporize a sufficient amount of precursor. More specifically, the injection method refers to a continuous vaporization process that may be carried out using the following transfer and vaporization apparatus:

Liquid transfer apparatus: A system that continuously supplies the liquid precursor to the vaporization apparatus in a state in which the flow rate is appropriately controlled by a transfer device (suction and pressurization), flow meter, and flow control devices such as valves.

Vaporization apparatus: A device that introduces liquid into a chamber under the appropriate reduced pressure and/or heating conditions for vaporization of the liquid.

Gas transfer apparatus: A device that supplies the gas that was generated to the CVD or ALD apparatus at an appropriately controlled flow rate without re-liquefying the gas. In particular, in order to enhance industrial productivity, it is preferable to carry out these continuous injection-type vaporization operations without using diluent gases such as other carrier gases.

More specifically, when no carrier gas is introduced into the composition when it is in a liquid state during evaporation, it is necessary to conduct the evaporation operation under more severe conditions such as a higher temperature and higher vacuum compared to when a carrier gas is introduced. Because high concentrations of the precursor vapor are generated even after evaporation, it is preferable to use a precursor that boasts higher stability. Moreover, the risk of blockage due to precursor decomposition is higher when the precursor is continuously introduced into the vaporization device and the evaporation operation is continuously carried out under high temperature and high vacuum conditions without a carrier gas. In the injection method, any blockage or other trouble in the liquid transfer apparatus, vaporization apparatus, or gas transfer apparatus can become a major problem. Furthermore, for industrial production using vaporization with the injection method, which requires strict productivity and operational stability, it is necessary to ensure that there is no blockage even after long-term operation without any accumulation of minute blockages, under a wide range of vaporization conditions (process window).

For example, stainless steel (such as SUS316L) that boasts excellent heat resistance and corrosion resistance may be used for the material of the piping. Furthermore, it is preferable to apply electrolytic polishing to the inside of the piping, which reduces the surface roughness and can to some extent inhibit the adsorption, decomposition, or formation of deposits of the precursor. Depending on the chemical properties of the precursor, it is also possible to apply an inner lining made of fluoropolymer such as polytetrafluoroethylene (PTFE).

### Method for Manufacturing Thin Film-Coated Substrates

The precursor that was transferred to the reaction chamber of a CVD or ALD apparatus according to the above-described method will form a thin film on the substrate under conditions such as plasma, heat, or reaction with other gases. In particular, plasma CVD (PECVD) and plasma ALD (PEALD) methods are preferably used to form high-performance insulating films with high productivity. Moreover, when forming a film, it is possible to form a higher performance film by combining the heating conditions and other reaction gas mixing conditions. The specific conditions for film formation are not particularly limited and may be established arbitrarily, depending on the scale and configuration of the apparatus, the desired film quality, and productivity. For example, in the case of a plasma CVD device for 4-inch substrates, the plasma output (W) should be at least 10 W, although 30 W or more is more preferable, and 50 W or more is even more preferable. The heating temperature of the chamber should be at least 20° C., although a temperature of 50° C. is preferable, and 100° C. or more is even more preferable. The upper limit should be 800° C. or less, although 600° C. or less is preferable, and 400° C. or less is even more preferable. Although it is not necessary to use a reactive mixed gas other than the precursor, it is possible to form a higher performance film by using a mixed gas with oxygen, for example. As noted above, the deposition conditions must be controlled according to the desired film quality. However, it is preferable for the precursor used for deposition to have a moderately high reactivity, ensuring that deposition may be carried out efficiently at a sufficient speed and uniformly over a wide range of deposition conditions.

Evaluation of the Reactivity of this Composition

The alkoxy groups bonded to the silane atoms, which are the active sites in the silane compounds contained in the compositions described herein, will react with reactive species derived from reactive gases such as the oxygen within CVD (PECVD) or ALD equipment to form a partially cross-linked structure represented by Si—O—Si bonds. As a result, these compositions exhibit functions making them suitable as an insulating film.

In this context, the reactivity of the compositions with water (where the Si-alkoxy group decomposes to form a Si—OH group) is adopted as an indicator for a test method to model the reactivity of the compositions with oxygen-derived reactive species. Therefore, the reactivity of the compositions in CVD (PECVD) or ALD equipment can be reasonably assessed based on the degree of decomposition after mixing the compositions with water.

More specifically, after mixing 1 mass part of a composition as described herein with 0.5 mass parts of water at room temperature and stirring the material for 15 minutes to produce a uniform solution, the mixture was then separated by gas chromatography, and the amount of the reaction was estimated from the chart area of the detector. In this case, the percentage of the total chart area of the reaction products with water, including silane atoms, divided by the total chart area of all of the compounds containing silane atoms, is defined as the decomposition rate and is used as an indicator of the reactivity.

Based on the fact that the reactivity will be adequately high as long as the decomposition rate is not too low and the fact that there will be no decrease in productivity during film formation, the decomposition rate should be 0.50% or more, although 1% or more is preferable, 5% or more is even more preferable, 10% or more is even more preferable, and 15% or more is most preferable. On the other hand, in order to prevent excessive or premature reactions, which could lead to non-uniform film formation, the decomposition rate should be 50% or less, although 40% or less is preferable, 35% or less is more preferable, and 30% or less is most preferable. The lower and upper limits of the decomposition rate can be freely combined, such as 0.50 to 50%, 1 to 50%, 5 to 40%, 10 to 35%, or 15 to 30%.

Containers and Sealed Articles Containing this Composition

One embodiment of the present disclosure relates to an article in which the composition as described herein is contained within a sealed container having one or more pipes. It is preferable that the sealed container is made of metal. It is also preferable that the sealed container is a pressure vessel. It is more preferable that the sealed container is a metal pressure vessel.

The composition may be primarily used as a precursor in CVD and ALD equipment. Generally, the precursors used in these devices are supplied in liquid or gaseous form, and it is necessary to maintain stability and purity during the process. Therefore, dedicated sealed containers are used to properly store these substances in a sealed manner. Additionally, the junction between the sealed container and the piping system for accurately transporting the precursor to the reaction device is also critical.

The above-mentioned sealed containers must meet the following requirements.
(1) Chemical stability: The container must be made of a material with high chemical resistance in order to prevent the precursor from reacting with the container material. For example, stainless steel or polymer materials are often used. Additionally, a special coating may be applied to the inner surface of the container in order to improve the chemical stability of the precursor.
(2) Sealing properties: The container must have a highly sealed structure to prevent leakage of the precursor and contamination from external substances. In particular, for liquid precursors with low vapor pressure, a design that minimizes vapor leakage is critical.
(3) Supply performance: In processes such as CVD and ALD, it is preferable for the container to have one or more pipes to ensure the stable and accurate supply of the precursor. An integrated design of the container and piping is preferable because it improves the efficiency of handling the precursor. The precursor can be vaporized by bubbling or baking, and the vaporized precursor can be stably supplied to the reaction apparatus, allowing for uniform and homogeneous deposition of the precursor within the reaction apparatus.
(4) Safety: When handling high-pressure gases or volatile liquids, it is preferable that the container is a pressure vessel designed to withstand pressure. It is also important to have safety mechanisms in place to deal with any potential leaks or damage.

The preferred design pressure for pressure vessels is between 5 MPa and 0.2 MPa, although 3 MPa to 0.8 MPa is preferable, and 2 MPa to 0.9 MPa is even more preferable. As for the volume of a general pressure vessel, it is preferably 10 L to 50 mL, although 5 L to 100 mL is preferable, and 3 L to 100 mL is even more preferable. As for the sealing properties of the pressure vessel required during depressurization (airtightness at vacuum and achievable vacuum degree as required by ASTM Standard D4991 or the like), it is preferable for it to be 10 torr or less, although 5 torr or less is preferable, 1 torr or less is even more preferable, and 0.1 torr or less is most preferable.

FIG. 1 shows a longitudinal sectional view of the entire precursor container, which consists of container body 1 and lid body 2, as an example of a sealed container for accommodating the precursor composition of the present disclosure. Various components, such as a liquid level sensor 3 (not shown in the figure) and liquid discharge piping 4 and liquid injection piping 5, are mounted on lid body 2. It is preferable for the multiple pipes and valves necessary for liquid injection, liquid discharge, gas insertion, and exhaust to be connected in this way. It is also preferable to replace the lid body with a lid body without holes for attaching various components when storing and transporting.

Although the precursor used in this embodiment needs to be heated to vaporize it, when the heating of the precursor is done using container body 1 itself, it is usually done by performing heating from the bottom of container body 1 using a heater or similar device. Therefore, it is preferable for this precursor container to have a structure that heats the bottom of container body 1 using a heat source, or for it to be used together with a heat source.

When transferring the precursor to the reaction apparatus side, if the precursor container is a bubbling container, a gas may be inserted from the outside to perform bubbling, which may cause the vapor pressure to decrease due to the loss of the heat of vaporization, or the supply amount may change due to changes in pressure. Therefore, by having at least the inner side wall be a vacuum insulation structure, it will be possible to minimize heat dissipation to the greatest extent possible.

Additionally, an outlet may be provided at the very bottom of the precursor container. By providing an outlet, sufficient cleaning may be performed even if there is an amount of precursor remaining. Depending on the precursor used, there is a risk of scaling inside the container during cleaning. In such cases, it is preferable to clean the inside with an acidic aqueous solution containing nitric acid or hydrofluoric acid once every few cleaning operations. However, because there is a risk of metal leaching due to nitric acid or hydrofluoric acid, it is necessary to perform a final cleaning with ultrapure water (preferably with a resistivity equivalent to 18 MQ2 cm), and it is preferable to have an outlet at the bottom for this purpose. This outlet allows for the circulation of ultrapure water inside the container and prevents the container from dissolving due to overflow of the ultrapure water containing the acidic aqueous solution, as well as preventing re-contamination from external or surface metal contamination.

The material of container body 1 and lid body 2 is stainless steel, but for smooth finishing, an austenitic stainless steel, which is an iron-based alloy, is preferable. More preferably, the material should be SUS 316 or SUS 304, and even more preferably, the material should be vacuum double-melted SUS 316L. Depending on the precursor, there may be a concern about reaction or corrosion with the metal constituting the container. To avoid this, it is preferable to perform electropolishing on the inner surface of the container (the part in contact with the silane compound). As a result, it will be possible to provide a CVD precursor supply container that is capable of being heated, maintaining temperature, producing minimal chemical residues, cleaning without charging, and reuse.

Moreover, because there is a concern about metal leaching, especially with acidic aqueous solutions that may be used during cleaning, it is preferable to select SUS 316L, which is an austenitic stainless steel that has undergone vacuum double melting in order to minimize trace metal content, as the metal for the inner surface of container body 1 and lid body 2. In addition, it is preferable to minimize metal leaching by performing electrolytic polishing.

### EXAMPLES

The invention will be further illustrated by the following examples, but the invention is not limited to these examples unless it exceeds the scope of the invention. Here, the term “part” in the examples refers to the mass unless otherwise specified.

Silane compound 1 and Silane compound 2 may be synthesized, for example, by the method described in U.S. Patent Application Publication No. 2009/0299086, and may be further distilled by a well-known method to obtain high-purity Silane compound 1 and Silane compound 2. Silane compound 3 may be procured from companies such as Angene Co., Ltd. or Arctom, for example, and may be further distilled by well-known methods as needed to obtain high-purity Silane compound 3.

### Comparative Example 1-1

As Silane compound 1, Silane compound 1A having formula (1A) was synthesized by the above-mentioned well-known method, resulting in Composition D-1 (content of Silane compound 1A: 99.94%). Furthermore, the content of Silane compound 4A having formula (4A) within Composition D-1 was 0.06%.

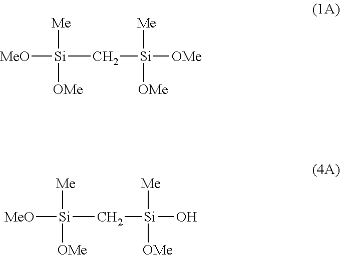 [SMILES: CO[Si](C)(C[Si](C)(OC)OC)OC ; CO[Si](C)(O)C[Si](C)(OC)OC]

In the above formulas, Me represents a methyl group and OMe represents a methoxy group.

### Evaluation of the Reactivity of the Composition

Under a N₂ atmosphere, a stir bar was placed in a 30 mL flask, and 1.0 g of Composition D-1 and 0.50 g of deionized water were added. The mixture was stirred at 40° C. for 15 minutes (at 600 rpm) in order to obtain a uniformly dissolved mixture. The resultant mixed solution was used to perform an analysis using the following method. Approximately 25 mg was sampled from the above-noted mixture, 2.5 mL of hexane was added, and the material was mixed to prepare a solution for analysis, which was performed using a gas chromatograph under the following analytical conditions. The detection limit for the GC analysis using this method is 0.01%, and if the corresponding compound peak is not detected, it is recorded as 0.00%. The compounds corresponding to each peak in the chart obtained by the FID detector were identified by separately analyzing their structure using a mass spectrometer or NMR, etc.

The GC analysis conditions were as follows:
GC apparatus: GC-2030 gas chromatograph, Shimadzu Corporation
Detector: FID detector (attached to GC-2030)
Column: Agilent DB-5, 30 m×0.25 mm φ×0.25 μm
Carrier gas: 1 mL/min (helium)
GC temperature: 40° C. (2 min, hold)→40° C. to 300° C. (13 min, heating rate 20° C./min)→300° C. (2 min, hold)
Injection volume: 1 μL
Injection temperature: 200° C.
FID detector temperature: 250° C.
Split ratio: 1/50

As a result of quantifying the decomposition products, the decomposition rate, which is an indicator of the reactivity of Composition D-1, was 0.44%, as shown in Table 1 in FIG. 5.

### Example of Embodiment 1-1

As Silane compound 2, Silane compound 2A having formula (2A) was synthesized by the above-mentioned well-known method (content of Silane compound 2A: 98.47%.) In addition, as Silane compound 3, Silane compound 3A having formula (3A) was procured from Angene Co., Ltd. as a product with 98% purity as described in the catalog, and this material was used as is. The above-noted Silane compound 1A, Silane compound 2A, and Silane compound 3A were uniformly mixed such that the area ratio of the peaks in gas chromatography was 99.75:0.13:0.12, resulting in Composition C-1. The FID chart of Composition C-1 before evaluating its reactivity is shown in FIG. 2. The details of the cause of the decrease in Silane compound 4A before and after mixing are unclear, but it is presumed that decomposition of Silane compound 4A during mixing may be a factor.

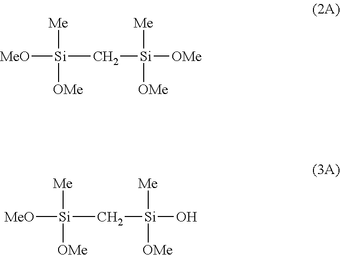 [SMILES: CO[Si](C)(C[Si](C)(OC)OC)OC ; CO[Si](C)(O)C[Si](C)(OC)OC]

The decomposition rate of Composition C-1, which was evaluated in the same manner as described in Comparative Example 1-1, was 20%, as shown in Table 1.

The FID chart of Composition C-1 after evaluating its reactivity is shown in FIG. 3. The detection times for each silane compound were as follows: Silane compound 1A: 7.52 minutes, Silane compound 2A: 6.92 minutes, Silane compound 3A: 6.48 minutes, hydrolysis product of Silane compound 1A: 7.38 minutes. In FIGS. 2 and 3, the major peaks are scaled out (saturated) due to the increased magnification in order to make the minor peaks easier to discern. However, the area ratio was calculated under conditions in which the major peaks were not scaled out.

### Example of Embodiment 1-2

The same method was used as the Example of Embodiment 1-1 other than mixing the material such that the ratio of the gas chromatography peak areas of Silane compound 1A, Silane compound 2A, and Silane compound 3A was 96.26:1.85:1.88, to obtain Composition C-2. Furthermore, Composition C-2 includes Silane compound 4A, and the actual ratio of the components was Silane compound 1A: Silane compound 2A: Silane compound 3A: Silane compound 4A=96.26:1.84:1.87:0.11.

The decomposition rate of Composition C-2, which was evaluated in the same manner as described in Comparative Example 1-1, was 45%, as shown in Table 1.

### Comparative Example 1-4

The same method was used as the Example of Embodiment 1-1 other than mixing the material such that the ratio of the gas chromatography peak areas of Silane compound 1A and Silane compound 3A was 95.50:0.50 to obtain Composition B-1. Furthermore, Composition B-1 includes Silane compound 4A, and the actual ratio of the components was Silane compound 1A: Silane compound 3A: Silane compound 4A=99.44:0.50:0.06.

The decomposition rate of Composition B-1, which was evaluated in the same manner as described in Comparative Example 1-1 was 0.53%, as shown in Table 1.

### Example of Embodiment 1-4

The same method was used as the Example of Embodiment 1-1 other than mixing the material such that the ratio of the gas chromatography peak areas of Silane compound 1A and Silane compound 2A was 95.50:0.50 to obtain Composition A-1. Furthermore, Composition A-1 includes Silane compound 4A, and the actual ratio of the components was Silane compound 1A: Silane compound 2A: Silane compound 4A=99.46:0.50:0.04. The details of the cause of the decrease in Silane compound 4A before and after mixing are unclear, but it is presumed that decomposition of Silane compound 4A may be a factor.

The decomposition rate of Composition A-1, which was evaluated in the same manner as described in Comparative Example 1-1, was 20%, as shown in Table 1.

### Comparative Example 1-2

The same method was used as the Example of Embodiment 1-1 other than mixing the material such that the ratio of the gas chromatography peak areas of Silane compound 1A, Silane compound 2A, and Silane compound 3A was 93.62:3.07:3.31 to obtain Composition D-2. The details of the cause of the decrease in Silane compound 4A before and after mixing are unclear, but it is presumed that decomposition of Silane compound 4A during mixing may be a factor.

The decomposition rate of Composition D-2, which was evaluated in the same manner as described in Comparative Example 1-1, was 95%, as shown in Table 1.

### Comparative Example 1-3

The same method was used as the Example of Embodiment 1-1 other than mixing the material such that the ratio of the gas chromatography peak areas of Silane compound 1A, Silane compound 2A, and Silane compound 3A was 96.24:2.28:1.48 to obtain Composition D-3. The details of the cause of the decrease in Silane compound 4A before and after mixing are unclear, but it is presumed that decomposition of Silane compound 4A during mixing may be a factor.

The decomposition rate of Composition D-3, which was evaluated in the same manner as described in Comparative Example 1-1, was 70%, as shown in Table 1.

### Example of Embodiment 1-5

The same method was used as the Example of Embodiment 1-1 other than mixing the material such that the ratio of the gas chromatography peak areas of Silane compound 1A and Silane compound 3A was 92.63:7.37 to obtain Composition B-2. The details of the cause of the decrease in Silane compound 4A before and after mixing are unclear, but it is presumed that decomposition of Silane compound 4A during mixing may be a factor.

The decomposition rate of Composition B-2, which was evaluated in the same manner as described in Comparative Example 1-1, was 46%, as shown in Table 1.

### Example of Embodiment 1-6

The same method was used as the Example of Embodiment 1-1 other than mixing the material such that the ratio of the gas chromatography peak areas of Silane compound 1A and Silane compound 2A was 98.05:1.95 to obtain Composition A-2. The details of the cause of the decrease in Silane compound 4A before and after mixing are unclear, but it is presumed that decomposition of Silane compound 4A during mixing may be a factor.

The decomposition rate of Composition A-2, which was evaluated in the same manner as described in Comparative Example 1-1, was 34%, as shown in Table 1.

### Example of Embodiment 1-7

The same method was used as the Example of Embodiment 1-1 other than mixing the material such that the ratio of the gas chromatography peak areas of Silane compound 1A and Silane compound 2A was 96.22:3.79 to obtain Composition A-3. The details of the cause of the decrease in Silane compound 4A before and after mixing are unclear, but it is presumed that decomposition of Silane compound 4A during mixing may be a factor.

The decomposition rate of Composition A-3, which was evaluated in the same manner as described in Comparative Example 1-1, was 30%, as shown in Table 1.

### Example of Embodiment 1-8

The same method was used as the Example of Embodiment 1-1 other than mixing Silane compound 1B having formula (1B) and Silane compound 3B having formula (3B), such that the gas chromatography peak area ratio would be 94.56:4.16, to obtain Composition K.

The decomposition rate of Composition K, which was evaluated in the same manner as described in Comparative Example 1-1, was 30%, as shown in Table 1.

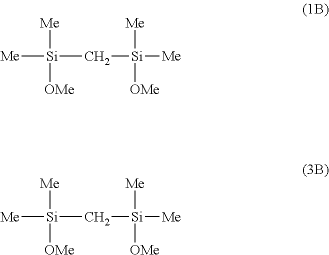 [SMILES: CO[Si](C)(C)C[Si](C)(C)OC ; CO[Si](C)(C)C[Si](C)(C)OC]

### Example of Embodiment 1-9

Composition D-1 that was used in Comparative Example 1-1 was stored under the following conditions for 6 months in order to obtain Composition E-1.

Storage conditions: 10 g of Composition D-1 was placed into a 50 mL vial (Maruemu Corporation, 50 mL brown screw-top vial, material: brown glass, cap: PP) and stored at 15° C. to 30° C. without nitrogen gas sealing. During the 6-month storage period, the cap was opened and closed more than 5 times within the atmosphere.

As a result of analyzing the resultant Composition E-1 using gas chromatography, it was found that it contained Silane compound 1A, Silane compound 4A, and Silane compound 5A that may be represented by the following formula (5A). Silane compound 1A: Silane compound 4A: Silane compound 5A=99.49:0.11:0.30.

The decomposition rate of Composition E-1, which was evaluated in the same manner as described for Composition D-1 in Comparative Example 1-1, was 31%.

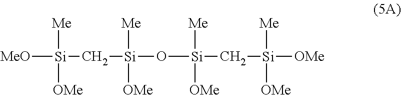 [SMILES: CO[Si](C)(C[Si](C)(OC)O[Si](C)(C[Si](C)(OC)OC)OC)OC]

### Comparative Example 1-5

Trimethylchlorosilane (TMSCl) was added to Composition E-1 that was obtained in Example of Embodiment 1-9 in order to obtain Composition E-2 with a chlorine atom content of 10 ppm (converted to the Cl mass relative to the total mass).

The decomposition rate of Composition E-2, which was evaluated in the same manner as described for Composition D-1 in Comparative Example 1-1, was 100%, and precipitation of solids was observed. The results are shown in Table 3.

As shown in the Examples of Embodiments 1-1, 1-2, and 1-4 to 1-8 in Table 1, the compositions containing an appropriate amount of Silane compound 2 and/or Silane compound 3 in addition to Silane compound 1 showed a suitable decomposition rate, excellent reactivity, and high film deposition speed, which are considered to ensure both productivity in film deposition and achieving uniform film quality.

Comparative Example 1-1, which does not contain Silane compound 2 or Silane compound 3, has a low decomposition rate and room for improvement in reactivity. Therefore, it may not be possible to achieve sufficient film deposition speed or productivity in film deposition.

With Comparative Examples 1-2 and 1-3, in which the amount of Silane compound 2 and/or Silane compound 3 relative to Silane compound 1 is excessive, the decomposition rate exceeds 50%, and it will likely be impossible to achieve uniform film quality in film deposition.

The presence of Silane compound 4 does not affect the decomposition rate if it is present in a certain amount or less. This is presumed to be due to the fact that Silane compound 4 is a compound that is necessarily generated when Silane compound 1 reacts with active species within the CVD apparatus.

As will be clear from Example of Embodiment 1-9, when Silane compound 5 is present in an appropriate amount, a composition with a favorable decomposition rate can be obtained.

### Analysis of the Metal Element Content

After adding sulfuric acid to approximately 0.35 g of Composition C-1, dry ashing was carried out using an IR furnace. Next, hydrofluoric acid was added, the material was evaporated and dried, and the residue was dissolved in dilute hydrochloric acid in order to bring the total volume up to the desired value. The metal content of Composition C-1 was measured by analyzing the solution using ICP mass spectrometry (ICP-MASS method). The results are shown in Table 2.

### Equipment

ICP-MASS analysis device: ELEMENT2, ThermoFisher Scientific
Detection limit: For each element listed in Table 2, 10 mass ppb (0.01 μg/g)

TABLE 2
Analysis of the Metal Element Content of Composition C-1

| | Analysis results (mass |
|---|---|
| Metal | ppb) |
| Ag | <10 |
| Al | 30 |
| Au | <10 |
| Ba | <10 |
| Ca | 30 |
| Cd | <10 |
| Co | <10 |
| Cr | <10 |
| Cu | <10 |
| Fe | 100 |
| Hf | <10 |
| In | <10 |
| K | <10 |
| Li | <10 |
| Mg | <10 |
| Mn | <10 |
| Na | 20 |
| Ni | <10 |
| Pb | <10 |
| Sn | 40 |
| Ti | 30 |
| V | <10 |
| W | <10 |
| Zn | 10 |

### Measurement of the Halogen Content

The halogen content of Compositions C-1, E-1, and E-2 was quantified using the following method. The results are shown in Table 3.

### Pretreatment

Approximately 20 to 30 mg of the sample and approximately 0.1 g of WO3 were placed on a magnetic boat for combustion absorption, the material was combusted in a combustion absorption apparatus, and the generated gas was absorbed in approximately 10 to 15 mL of absorption liquid. The absorption liquid was quantified by separating it into F⁻, Cl⁻, Br⁻, and I⁻ using the Anion-IC device described below.

### Method for Measuring the F Content

IC separation column: AS15
Eluting solvent: 20 mM NaOH
Eluting solvent flow rate: 1.0 mL/min
Detection mode: Electrical conductivity
Suppressor: Dione ADRS 600 (External mode)
Input volume: 100 μL (using an autosampler)

### Method for Measuring the Cl and Br Content

IC separation column: AS12A
Eluting solvent: Na₂CO₃ 2.7 mM, NaHCO₃ 0.3 mM
Eluting solvent flow rate: 1.5 mL/min
Detection mode: Electrical conductivity
Suppressor: Dione ADRS 600 (recycle mode)
Input volume: 100 μL (using an autosampler)

### Method for Measuring the I Content

IC separation column: AS20
Eluting solvent: 20 mM NaOH
Eluting solvent flow rate: 1.0 mL/min
Detection mode: Electrical conductivity
Suppressor: Dione ADRS 600 (External mode)
Input volume: 100 μL (using an autosampler)

### Equipment

Combustion absorption system: NittoSeiko Analytech, AQF-2100H
IC: Thermo Fisher Scientific, ICS6000 and ICS1600

TABLE 3
Summary of Metal Element Contents

| | F | C1 | Br | I | Decomposition |
|---|---|---|---|---|---|
| | (Mass | (Mass | (Mass | (Mass | rate |
| Element | ppm) | ppm) | ppm) | ppm) | (%) |
| Composition | 1.4 | 2.9 | 2.3 | <2 | 20 |
| C-1 | | | | | |
| Composition | <0.4 | 1.1 | <3 | <2 | 31 |
| E-1 | | | | | |
| Composition | <0.4 | 9.9 | <3 | <2 | 100 |
| E-2 | | | | | |

As shown in Table 2, the metal content was 100 mass ppb or less for all of the metal elements. The inequality sign (<) indicates that the value is below the detection limit.

As shown in Table 3, the halogen atom (F, Cl, Br, I) contents of Composition C-1 and E-1 were 10 mass ppm (10 μg/g) or less. The inequality sign (<) indicates that the value is below the detection limit. In particular, Cl atoms, which are a concern due to potential contamination from raw materials, equipment, containers, or the environment, was found to be present at an extremely low content.

In this way, it was found that this composition boasts moderate reactivity while achieving the extremely low content of metal elements and halogen atoms that is required for semiconductor materials.

On the other hand, in Composition E-2, to which trimethylsilyl chloride (TMSCl) was added as a model experiment, the decomposition rate increased from 31% to 100% when compared to Composition E-1. Based on these results, it can be inferred that the presence of a certain amount of chlorine derived from the Si—Cl bond causes decomposition to accelerate excessively, leading to solidification and problems such as heterogeneous film quality.

### Evaluation of the Boiling Point and Weight Loss of the Composition

When depositing films using PECVD, the boiling point of the composition and the weight loss may be used as the indicators to achieve uniform films. In order to measure these parameters, an analysis was conducted using a differential thermal thermogravimetric simultaneous measurement device under the following analysis conditions. The conditions for simultaneous differential thermal thermogravimetric measurements are as follows:
Differential thermal thermogravimetric simultaneous measurement device: TG-DTA 8122, Rigaku Corporation
Sample mass: Approximately 5 mg
Heating rate: 10° C./min
Set point temperature: 400° C.
Atmosphere: Nitrogen

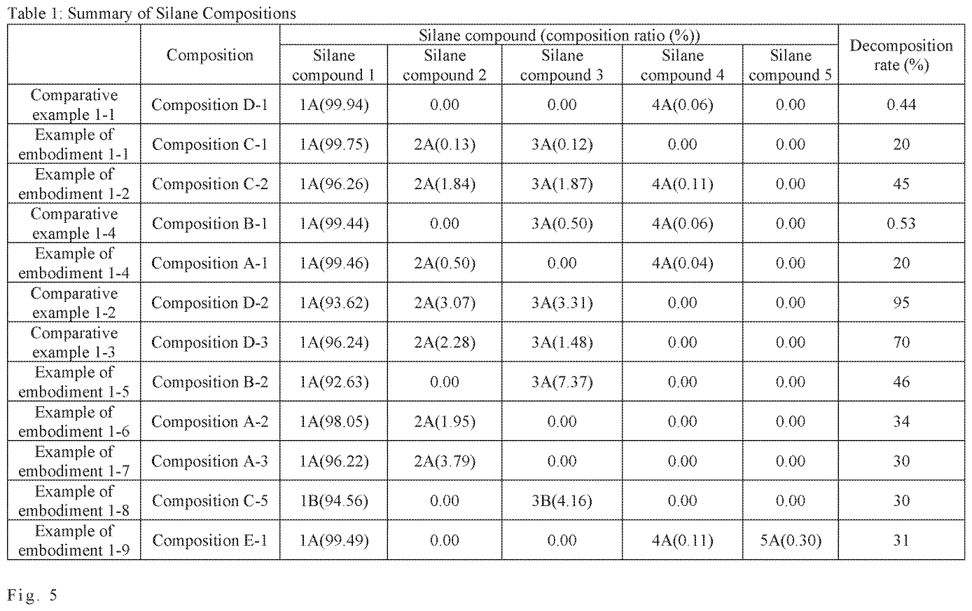

The results of the evaluation of the boiling point and weight loss for Composition C-1 are shown in FIG. 4. As shown in FIG. 4, based on the fact that there is only a single endothermic point of the DTA curve at 118.69° C., and the weight decreased by 100% at this endothermic point, the boiling point of Composition C-1 is found at only one point at 118. 69° C., and it did not affect the uniform film formation.

### Example of Embodiment 2-1

Composition C-1 obtained in the Example of Embodiment 1-1 was used to fill a sealed container made of SUS 316 with two valves under a nitrogen atmosphere, and the two valves were closed to seal the container. Container details: SUS container for CVD, SAMCO, TR3017S-3, capacity: 200 mL, hermetic seal (ultimate vacuum): 0.1 torr or less, pressure resistance (design pressure): 0.98 MPa, cleaned with acetone and ultrapure water prior to filling.

When using Composition C-1 filled in the container, film formation was carried out using the plasma CVD method described below. The film formation proceeded at a sufficient speed, making it possible to obtain a high-strength, uniform insulating film.

### Method of Film Formation Using the CVD Method

Substrate: 3-inch P-type silicon wafer
CVD equipment: SAMCO, PD-10C1 liquid source plasma CVD equipment
Cylinder temperature: 80° C.
Flow path temperature: 80° C.
Vacuum level: 100 Pa
Carrier gas introduced into the precursor liquid: None The evaporation operation was conducted without introducing or bubbling a carrier gas
Carrier gas: Ar, flow rate 40 sccm, mixed after evaporation
Chamber temperature: 200° C.
Plasma conditions: 75 W, 13.56 MHz
Film deposition time: 1 min

### Example of Embodiment 2-2

The deposition conditions in the Example of Embodiment 2-1 were changed by altering the plasma power from 75 W to 125 W, resulting in the formation of a uniform insulating film.

### Example of Embodiment 2-3

The deposition conditions in the Example of Embodiment 2-1 were changed by altering the chamber temperature from 200° C. to 300° C., resulting in the formation of a uniform insulating film.

### Example of Embodiment 2-4

The deposition conditions in Example of Embodiment 2-1 were modified by changing the carrier gas from Ar: flow rate 40 sccm to a mixed gas of Ar: flow rate 40 sccm and O₂: flow rate 10 sccm, resulting in a uniform insulating film.

### Evaluation of the Film

### Example of Embodiment 3-1

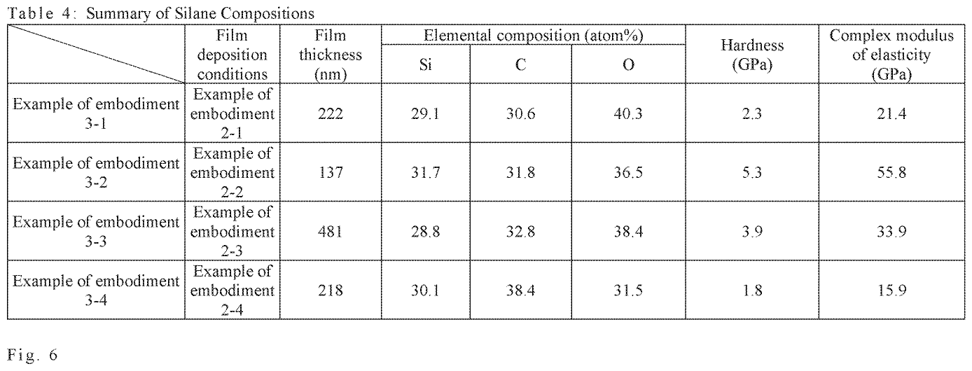

The films obtained in the Examples of Embodiment 2-1 to 2-4 were evaluated using the following methods, and the results are shown in Table 4 in FIG. 6.

### Measurement of Film Thickness

Measurement method: The film thickness was measured by performing a fitting analysis using a spectroscopic ellipsometer.
Equipment: Spectroscopic ellipsometer (J. A. Woollam Inc., M2000X)
Measurement wavelength: (245 to 1000 nm)
Incidence angle: 68 to 75° (0.5° increments)
Analysis method: The n-Cauchy model was used as a dielectric function, and a fitting analysis was performed in order to calculate the film thickness.
Number of measurement points: Five points were measured from the inside to the periphery of the wafer, and the average value was taken as the film thickness. In addition, the in-plane uniformity of the film thickness (%) was calculated as {(film thickness of the point that deviated the most from the average value (nm)−average film thickness (nm))/(average film thickness (nm))×100}. As a result, all of the above-noted values fell within a range of plus or minus 5% in all of the examples.

### Measurement of the Elemental Composition

Measurement method: The elemental composition (atom %) of Si, C, and O was measured using X-ray photoelectron spectroscopy (XPS: X-ray Photoelectron Spectroscopy).
Instrument: KRATOS ULTRA2
X-ray source: Monochromatic Al-Kα
Output: Wide spectrum: 15 kV to 75 W (5 mA), Narrow spectrum: 15 kV to 225 W (15 mA)
Spectral system: Pass energy Wide spectrum: 160 eV, Narrow spectrum: 10 eV
Analysis method: Peaks corresponding to C 1s, O 1s, Si 2p were analyzed, and the composition (atom %) of Si, C, and O were calculated. In all of the examples of embodiment, Si, C, and O elements corresponding to the composition of the precursor that was used were detected.

### Measurement of the Hardness and Complex Elastic Modulus

Measurement method: The hardness (GPa) and complex elastic modulus (GPa) were measured using a nanoindenter.
Instrument: Bruker TI980
Plunger: The plunger attached to the instrument (manufacturer's number: TI-0039), Material: diamond, Shape: Berkovich
Measurement conditions: Load: 5 seconds, Hold: 2 seconds, Load release: 5 seconds, Lift height: 50 nm, Set point: 0.5 μN

### Comparative Example 2-1

When Composition D-1 obtained in Comparative Example 1-1 was used under the same conditions as described in Example of embodiment 3-1 to perform CVD film deposition, a good insulating film was obtained.

On the other hand, there is room for improvement in the deposition rate, and it is speculated that the productivity may be insufficient. This tendency is more pronounced as the scale of the deposition equipment increases, the piping becomes longer, and the deposition time becomes longer.

In the above-noted examples of embodiment, specific forms of the present invention have been shown, but the above-noted examples are merely illustrative and should not be construed as limiting. Various modifications that are obvious to those skilled in the art may be envisioned to be within the scope of the present invention.

We claim:

1. A composition comprising a silane compound 1 having formula (1) and a silane compound 2 having formula (2), wherein, as calculated from area percentages in gas chromatography, a content of the silane compound 1 is 95.0% or higher, a content of the silane compound 2 is 0.05 to 5.0%, and wherein the composition contains less than 0.01% of a silane compound 3 having formula (3): 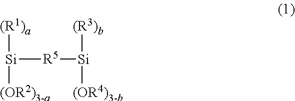
wherein R¹ to R⁴ represent the same or different hydrocarbon groups having 1 to 10 carbon atoms, a and b represent the same or different integers of 0 to 3, a+b is an integer of 5 or less, and R⁵ represents a hydrocarbon group with 1 to 6 carbon atoms; 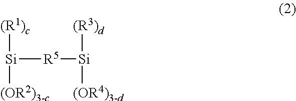
wherein c and d represent the same or different integers of 0 to 3, the sum of c and d is greater than the sum of a and b in formula (1); 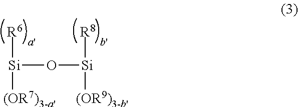
wherein R⁶ to R⁹ represent the same or different hydrocarbon groups having 1 to 10 carbon atoms, and a′ and b′ represent the same or different integers from 0 to 3.

2. A composition comprising a silane compound 1 having formula (1) and a silane compound 3 having formula (3); wherein, as calculated from area percentages in gas chromatography, a content of the silane compound 1 is 90.0% or higher, a content of the silane compound 3 is 0.80 to 10.0%, and wherein the composition contains less than 0.01% of a silane compound 2 having formula (2): 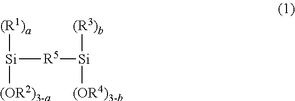
wherein R¹ to R⁴ represent the same or different hydrocarbon groups having 1 to 10 carbon atoms, a and b represent the same or different integers of 0 to 3, a+b is an integer of 5 or less, and R⁵ represents a hydrocarbon group with 1 to 6 carbon atoms; 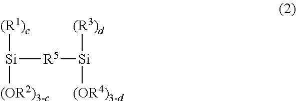
wherein c and d represent the same or different integers of 0 to 3, the sum of c and d is greater than the sum of a and b in formula (1); 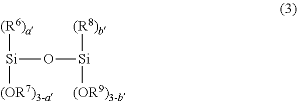
wherein R⁶ to R⁹ represent the same or different hydrocarbon groups having 1 to 10 carbon atoms, and a′ and b′ represent the same or different integers from 0 to 3.

3. A composition comprising a silane compound 1 having formula (1), a silane compound 2 having formula (2), and a silane compound 3 having formula (3); wherein, as calculated from area percentages in gas chromatography, a content of the silane compound 1 is 95.0% or higher, a content of the silane compound 2 is 0.05 to 2.0%, and a content of the silane compound 3 is 0.05 to 2.0%: 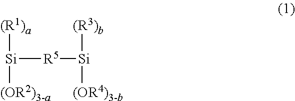
wherein R¹ to R⁴ represent the same or different hydrocarbon groups having 1 to 10 carbon atoms, a and b represent the same or different integers of 0 to 3, a+b is an integer of 5 or less, and R⁵ represents a hydrocarbon group with 1 to 6 carbon atoms; 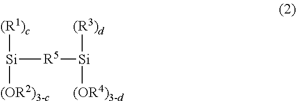
wherein c and d represent the same or different integers of 0 to 3, the sum of c and d is greater than the sum of a and b in formula (1); 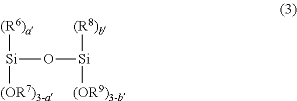
wherein R⁶ to R⁹ represent the same or different hydrocarbon groups having 1 to 10 carbon atoms, and a′ and b′ represent the same or different integers from 0 to 3.

4. The composition according to claim 1, wherein the content of the silane compound 2 is 0.10 to 2.0%.

5. The composition according to claim 2, wherein the content of the silane compound 3 is 0.90 to 5.0%.

6. The composition according to claim 3, wherein the content of the silane compound 1 is 99.0% or higher, the content of the silane compound 2 is 0.05 to 0.20%, and the content of the silane compound 3 is 0.05 to 0.20%.

7. The composition according to claim 1, wherein in formula (1), a and b represent the same or different integers of 0 to 2, and in formula (2), c and d represent the same or different integers of 0 to 2.

8. The composition according to claim 1, further comprising an additional silane compound 5 having formula (5), wherein a content of the additional silane compound 5, as calculated from an area percentage in gas chromatography, is 0.10 to 2.0%: 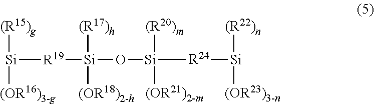
wherein R¹⁵ to R¹⁸ and R²⁰ to R²³ represent the same or different hydrocarbon groups having 1 to 10 carbon atoms, g and n represent the same or different integers of 0 to 3, h and m represent the same or different integers of 0 to 2, and R¹⁹ and R²⁴ represent the same or different hydrocarbon groups having 1 to 6 carbon atoms.

9. The composition according to claim 1, wherein a halogen content is 10 mass ppm or less for each halogen atom.

10. A composition comprising a silane compound 1 having formula (1) and a silane compound 5 having formula (5), wherein, as calculated from area percentages in gas chromatography, a content of the silane compound 1 is 95.0% or higher and a content of the silane compound 5 is 0.05 to 2.0%, and wherein the composition contains less than 0.01% of a silane compound 2 having formula (2) and less than 0.01% of a silane compound 3 having formula (3), and wherein a chlorine atom content is 9 mass ppm or less: 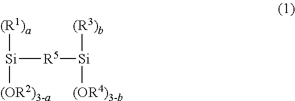
wherein R¹ to R⁴ represent the same or different hydrocarbon groups having 1 to 10 carbon atoms, a and b represent the same or different integers of 0 to 3, a+b is an integer of 5 or less, and R⁵ represents a hydrocarbon group having 1 to 6 carbon atoms; 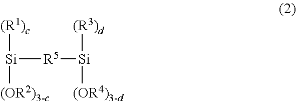
wherein c and d represent the same or different integers of 0 to 3, the sum of c and d is greater than the sum of a and b in formula (1); 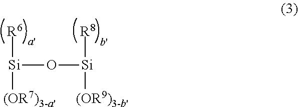
wherein R⁶ to R⁹ represent the same or different hydrocarbon groups having 1 to 10 carbon atoms, and a′ and b′ represent the same or different integers from 0 to 3; 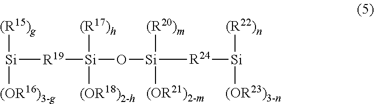
wherein R¹⁵ to R¹⁸ and R²⁰ to R²³ represent the same or different hydrocarbon groups having 1 to 10 carbon atoms, g and n represent the same or different integers of 0 to 3, h and m represent the same or different integers of 0 to 2, and R¹⁹ and R²⁴ represent the same or different hydrocarbon groups having 1 to 6 carbon atoms.

11. The composition according to claim 1, wherein a metal content is 100 mass ppb or less for each metal element.

12. The composition according to claim 1, wherein the composition is substantially free of solvent.

13. A method for manufacturing a thin film, comprising forming a thin film by chemical vapor deposition (CVD) or atomic layer deposition (ALD) using the composition according to claim 1.

14. A method for manufacturing a thin film on a substrate, comprising vaporizing the composition according to claim 1, introducing the vaporized composition into a reaction chamber, and forming a thin film on a substrate in the reaction chamber using the vaporized composition.

15. The method for manufacturing according to claim 14, wherein the composition is vaporized by an injection method.

16. A transfer method comprising vaporizing the composition according to claim 1 and transporting the vaporized composition through a pipeline.

17. A thin film on a substrate obtained by the manufacturing method according to claim 14.

18. A method for manufacturing a thin film, comprising spin coating a thin film using the composition according to claim 1.

19. An article containing the composition according to claim 1 in a sealed container having one or more pipelines.

20. The article according to claim 19, wherein the sealed container is a metal pressure vessel.

21. The method for manufacturing a thin film on a substrate according to claim 14, wherein the composition is vaporized without introducing a carrier gas into the composition.

22. The thin film on a substrate according to claim 17, wherein an in-plane uniformity is within ±5% and a hardness is 1 GPa or more.

23. The method for manufacturing a thin film according to claim 13, wherein an in-plane uniformity of the thin film is within ±5% and a hardness is 1 GPa or more.

24. The composition according to claim 2, further comprising an additional silane compound 5 having formula (5), wherein a content of the additional silane compound 5, as calculated from an area percentage in gas chromatography, is 0.10 to 2.0%: 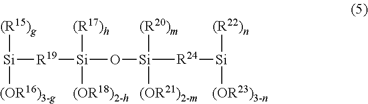
wherein R¹⁵ to R¹⁸ and R²⁰ to R²³ represent the same or different hydrocarbon groups having 1 to 10 carbon atoms, g and n represent the same or different integers of 0 to 3, h and m represent the same or different integers of 0 to 2, and R¹⁹ and R²⁴ represent the same or different hydrocarbon groups having 1 to 6 carbon atoms.

25. The composition according to claim 2, wherein a halogen content is 10 mass ppm or less for each halogen atom.

26. The composition according to claim 2, wherein a metal content is 100 mass ppb or less for each metal element.

27. The composition according to claim 2, wherein the composition is substantially free of solvent.

28. The composition according to claim 3, further comprising an additional silane compound 5 having formula (5), wherein a content of the additional silane compound 5, as calculated from an area percentage in gas chromatography, is 0.10 to 2.0%: 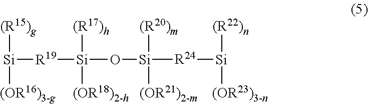
wherein R¹⁵ to R¹⁸ and R²⁰ to R²³ represent the same or different hydrocarbon groups having 1 to 10 carbon atoms, g and n represent the same or different integers of 0 to 3, h and m represent the same or different integers of 0 to 2, and R¹⁹ and R²⁴ represent the same or different hydrocarbon groups having 1 to 6 carbon atoms.

29. The composition according to claim 3, wherein a halogen content is 10 mass ppm or less for each halogen atom.

30. The composition according to claim 3, wherein a metal content is 100 mass ppb or less for each metal element.

31. The composition according to claim 3, wherein the composition is substantially free of solvent.

32. The composition according to claim 1, wherein a metal content is 100 mass ppb or less for each metal element.

33. The composition according to claim 1, wherein the composition is substantially free of solvent.
